(19) United States
(12) Patent Application Publication
(10) Pub. No.: US 2026/0204218 A1
(43) Pub. Date: Jul. 16, 2026

(54) SUB-PIXEL, DISPLAY DEVICE INCLUDING THE SAME, AND ELECTRONIC DEVICE INCLUDING THE DISPLAY DEVICE

(71) Applicant: Samsung Display Co., LTD., Yongin-si (KR)

(72) Inventors: Kyung Bae KIM, Yongin-si (KR); Dong Woo KIM, Yongin-si (KR); Yeon Kyung KIM, Yongin-si (KR); Yong Hee LEE, Yongin-si (KR)

(21) Appl. No.: 19/365,550

(22) Filed: Oct. 22, 2025

(30) Foreign Application Priority Data
Jan. 14, 2025 (KR) 10-2025-0005437

(51) Int. Cl. G09G 3/3233

(52) U.S. Cl. CPC G09G 3/3233; G09G 2300/0426; G09G 2300/043

(57) ABSTRACT

A sub-pixel includes a first capacitor which maintains a potential difference between a first node and a third node, a second capacitor which maintains a potential difference between a second node and a power line to which a constant voltage is applied, and a third capacitor which maintains a potential difference between a first node and a third node.

This application claims priority to Korean Patent Application No. 10-2025-0005437, filed on Jan. 14, 2025, and all the benefits accruing therefrom under 35 U.S.C. § 119, the content of which in its entirety is herein incorporated by reference.

### BACKGROUND

### 1. Field

Embodiments of the disclosure relate to a sub-pixel, a display device including the sub-pixel, an electronic device including the display device, and a driving method thereof.

### 2. Description of the Related Art

With the development of information technology, the importance of a display device, which is a connection medium between a user and information, is being highlighted. Accordingly, the use of display devices such as liquid crystal display devices and organic light-emitting display devices is increasing.

The display device may display images of various luminances by allowing a driving current of an appropriate magnitude to flow through the light-emitting element therein. Easier control of the magnitude of the driving current may improve visibility.

### SUMMARY

A technical problem to be solved is to provide a sub-pixel to control the magnitude of a driving current easily, a display device including the same, an electronic device including the same and a driving method thereof.

In an embodiment of the disclosure, a sub-pixel including a first transistor including a gate electrode electrically connected to a first node, the first transistor being connected between a second node and a third node, the second node being electrically connected to a first power line, a light-emitting element connected between the second node and a second power line, a second transistor which switches an electrical connection between the first node and a data line, a third transistor which switches an electrical connection between the second node and a third power line, a fourth transistor which switches an electrical connection between the first power line and the third node, a first capacitor which maintains a potential difference between the first node and the third node, a second capacitor which maintains a potential difference between the second node and a power line to which a constant voltage is applied, and a third capacitor which maintains potential difference between the first node and the third node.

In an embodiment, the second capacitor may include a first electrode electrically connected to the second node and a second electrode electrically connected to the power line to which the constant voltage is applied.

In an embodiment, a second power supply voltage may be applied to the second power line. The constant voltage may be the same as the second power supply voltage.

In an embodiment, a third power supply voltage may be applied to the third power line. The constant voltage may be the same as the third power supply voltage.

In an embodiment, the power line to which the constant voltage is applied may be different from the first power line, the second power line, and the third power line.

In an embodiment, the first electrode of the second capacitor and the second electrode of the second capacitor may be disposed in a same layer.

In an embodiment, a capacitance of the second capacitor may be greater than a capacitance between an anode electrode and a cathode electrode of the light-emitting element.

In an embodiment, the first transistor, the second transistor, and the fourth transistor may include a P-type semiconductor. The third transistor may include an N-type semiconductor.

In an embodiment, a first power supply voltage may be applied to the first power line. A third power supply voltage may be applied to the third power line. The first power supply voltage may be applied to body electrodes of the first transistor, the second transistor, and the fourth transistor, respectively. The third power supply voltage may be applied to the body electrode of the third transistor.

In an embodiment of the disclosure, a display device includes a display panel in which a plurality of sub-pixels are disposed, and in which a plurality of data lines, a plurality of first gate lines, a plurality of second gate lines, and a plurality of light emission control lines electrically connected to the plurality of sub-pixels are disposed, a data driver which supplies a data voltage to the plurality of data lines, and a gate driving circuit which supplies a signal to the plurality of first gate lines, the plurality of second gate lines, and the plurality of light emission control lines, where at least one of the plurality of sub-pixels includes a first transistor including a gate electrode electrically connected to a first node, is the first transistor being connected between a second node and a third node, the second node being electrically connected to a first power line, a light-emitting element connected between the second node and a second power line, a second transistor which switches an electrical connection between the first node and a corresponding one of the plurality the data lines, a third transistor which switches an electrical connection between the second node and a third power line, a fourth transistor which switches an electrical connection between the first power line and the third node, a first capacitor which maintains a potential difference between the first node and the third node, a second capacitor which maintains the potential difference between the second node and a power line to which a constant voltage is applied, and a third capacitor which maintains potential difference between the first node, and the third node.

In an embodiment, the second transistor may include a gate electrode electrically connected to a corresponding one of the plurality of first gate lines.

In an embodiment, the second transistor may be turned on in response to a first scan signal having a low-level applied to the gate electrode.

In an embodiment, the third transistor may include a gate electrode electrically connected to a corresponding one of the plurality of second gate lines.

In an embodiment, the third transistor may be turned on in response to a second scan signal having a high-level applied to the gate electrode.

In an embodiment of the disclosure, an electronic device includes a processor that outputs an input image data, a controller that converts the input image data to output an image data, a display panel in which a plurality of sub-pixels are disposed, and in which a plurality of data lines, a plurality of first gate lines, a plurality of second gate lines, and a plurality of light-emission control lines electrically connected to the plurality of sub-pixels are disposed, a data driver which supplies a data voltage corresponding to the image data to the plurality of data lines, and a gate driving circuit which supplies a signal to the plurality of first gate lines, the plurality of second gate lines, and the plurality of light emission control lines, where at least one of the plurality of sub-pixels includes a first transistor including a gate electrode electrically connected to a first node, the first transistor being connected between a second node and a third node, the second node being electrically connected to a first power line, a light-emitting element connected between the second node and a second power line, a second transistor which switches an electrical connection between the first node and a corresponding one of the plurality the data lines, a third transistor which switches an electrical connection between the second node, and a third power line, a fourth transistor which switches an electrical connection between the first power line and the third node, a first capacitor which maintains a potential difference between the first node and the third node, a second capacitor which maintains a potential difference between the second node and a power line to which a constant voltage is applied, and a third capacitor which maintains a potential difference between the first node and the third node.

In an embodiment, the controller may generate the image data based on the capacitance of the first capacitor and the capacitance of the third capacitor.

In an embodiment of the disclosure, a method for driving an electronic device including a first transistor and a light-emitting element electrically connected to the first transistor, the method including: applying a data voltage to a first electrode of a first capacitor electrically connected to a gate electrode of the first transistor, and applying a first power supply voltage to a second electrode of the first capacitor electrically connected to a source electrode of the first transistor, applying the data voltage to the gate electrode of the first transistor and storing a first threshold voltage of the first transistor in the first capacitor, applying the first power supply voltage to the second electrode of the second capacitor, and reflecting a voltage fluctuation amount of the second electrode of the first capacitor to the first electrode in a ratio corresponding to a capacitance of the first capacitor, and fluctuating a voltage of a second electrode of a third capacitor electrically connected to a drain electrode of the first transistor by a driving current flowing through the first transistor, and reflecting a voltage fluctuation amount of the second electrode of the third capacitor in a ratio corresponding to a capacitance of the third capacitor to the first electrode of the third capacitor, where the first electrode of the third capacitor is electrically connected to a gate electrode of the first transistor.

In an embodiment, the ratio corresponding to the capacitance of the first capacitor may be calculated by dividing the capacitance of the first capacitor by a value obtained by adding the capacitance of the first capacitor and the capacitance of the third capacitor.

In an embodiment, the ratio corresponding to the capacitance of the third capacitor may be calculated by dividing the capacitance of the third capacitor by a value obtained by adding the capacitance of the first capacitor and the capacitance of the third capacitor.

In an embodiment, the electronic device may further include a second capacitor including a first electrode electrically connected to a drain electrode of the first transistor and a second electrode to which a constant voltage is applied. A ripple voltage may be applied to the first electrode of the second capacitor in the reflecting the voltage fluctuation amount of the second electrode of the first capacitor in the first electrode of the first capacitor in a ratio corresponding to the capacitance of the first capacitor.

### BRIEF DESCRIPTION OF THE DRAWINGS

The above and other features of the disclosure will become more apparent by describing in further detail embodiments thereof with reference to the accompanying drawings, in which:

FIG. 1 is a system block diagram of an embodiment of a display device according to the disclosure.

FIG. 2 is a block diagram illustrating an embodiment of any one of the sub-pixels of FIG. 1.

FIG. 3 is an equivalent circuit diagram of an embodiment of a sub-pixel according to the disclosure.

FIG. 4 is an equivalent circuit diagram of an embodiment of a sub-pixel according to the disclosure.

FIG. 5 is an equivalent circuit diagram of an embodiment of a sub-pixel according to the disclosure.

FIG. 6 is an embodiment of the first capacitor.

FIG. 7 is an embodiment of a second capacitor.

FIG. 8 is a method of driving an embodiment of a sub-pixel according to the disclosure.

FIGS. 9 to 12 are diagrams for explaining the driving method of FIG. 8 with respect to the sub-pixels of FIG. 3.

FIG. 13 is a method of driving an embodiment of a sub-pixel according to the disclosure.

FIGS. 14 to 17 are diagrams for explaining the driving method of FIG. 13 with respect to the sub-pixels of FIG. 3.

FIG. 18 is a plan view showing an embodiment of the display panel of FIG. 1.

FIG. 19 is an exploded perspective view showing a part of the display panel of FIG. 18.

FIG. 20 is a plan view showing an embodiment of any one of the pixels of FIG. 19.

FIG. 21 is a cross-sectional view taken along line I-I′ of an embodiment of FIG. 20 according to the disclosure.

FIG. 22 is a cross-sectional view taken along line I-I′ of an embodiment of FIG. 20 according to the disclosure.

FIG. 23 is an enlarged view showing an area A of FIG. 22.

FIG. 24 is a cross-sectional view showing an embodiment of a part of a light-emitting structure included in any one of the first to third light-emitting elements of FIG. 21 and the first to third light-emitting elements of FIG. 22.

FIG. 25 is a cross-sectional view showing another embodiment of a portion of a light-emitting structure included in any one of the first to third light-emitting elements of FIG. 21 and the first to third light-emitting elements of FIG. 22.

FIG. 26 is a plan view showing another embodiment of any one of the pixels of FIG. 19.

FIG. 27 is a plan view showing another embodiment of any one of the pixels of FIG. 19.

FIG. 28 is a block diagram illustrating an embodiment of a display system.

FIG. 29 is a perspective view showing an embodiment of an application of the display system of FIG. 28.

FIG. 30 is a diagram showing a head-mounted display device worn by the user of FIG. 29.

### DETAILED DESCRIPTION OF THE EMBODIMENT

Hereinafter, various embodiments of the disclosure will be described in detail with reference to the accompanying drawings so that those skilled in the art may easily implement the embodiments. The disclosure may be embodied in many different forms and is not limited to the embodiments described herein.

In order to clearly explain the disclosure, parts not related to the description may be omitted, and the same or similar components are denoted by the same reference numerals throughout the specification. Accordingly, the aforementioned reference numerals may also be used in other drawings.

In addition, the size and thickness of each component shown in the drawings are arbitrarily shown for convenience of description, and therefore, the disclosure is not necessarily limited to what is shown. Thicknesses may be exaggerated to clearly represent multiple layers and regions in the drawings.

Also, the expression “same” in the description may mean “substantially the same”. In other words, it may be the same enough that a person with ordinary knowledge may understand that they are the same. Other expressions may also be those in which “substantially” is omitted.

The terms first, second, etc. may be used to describe various components, but the components should not be limited by the terms. The above terms are used only for the purpose of distinguishing one component from another. For example, a first component may be named a second component, and similarly, a second component may also be named a first component, without departing from the scope of the disclosure. The singular forms “a”, “an” and “the” include plural references unless the context clearly requires otherwise.

The terms “below”, “under,” “above”, “on,” and the like are used to describe the association of the components shown in the drawing figures. The above terms are relative concepts and are explained with reference to the directions indicated in the drawings.

Unless otherwise defined, all terms (including technical and scientific terms) used herein have the same meaning as commonly understood by one of ordinary skill in the art to which this disclosure belongs. In addition, terms such as those defined in commonly used dictionaries should be interpreted as having a meaning that is consistent with the meaning in the context of the relevant art, and are expressly defined herein unless interpreted in an ideal or overly formal sense.

It is to be understood that the terms “comprise” or “have” and the like are intended to designate the presence of a feature, number, step, operation, component, part, or combination thereof described in the specification, and do not preclude the presence or possibility of addition of one or more other features, numbers, steps, operations, components, parts, or combinations thereof.

Hereinafter, embodiments of the disclosure will be described in detail with reference to the accompanying drawings.

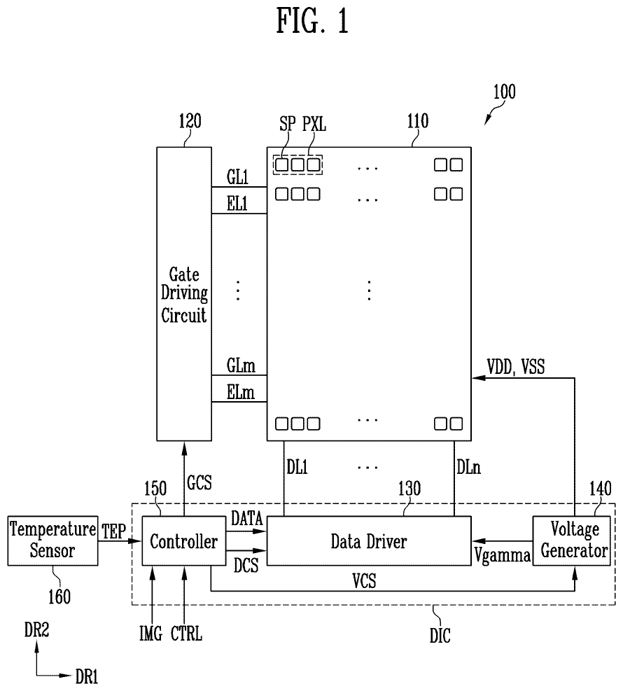

FIG. 1 is a system block diagram of an embodiment of a display device 100 according to the disclosure.

Referring to FIG. 1, a display device 100 in embodiments of the disclosure may include a display panel 110, a gate driving circuit 120, a data driver 130, a voltage generator 140, a controller 150, a temperature sensor 160, or the like.

The display panel 110 may include a plurality of sub-pixels SP. First to m-th gate lines GL1 to GLm (m is an integer of 2 or more) connected to a plurality of sub-pixels SP may be disposed on the display panel 110. First to n-th data lines DL1 to DLn (n is an integer of 2 or more) connected to a plurality of sub-pixels SP may be disposed on the display panel 110.

The plurality of sub-pixels SP may be connected to the gate driving circuit 120 through the first to m-th gate lines GL1 to GLm. The plurality of sub-pixels SP may be connected to the data driver 130 through the first to n-th data lines DL1 to DLn.

Each of the plurality of sub-pixels SP may include at least one light-emitting element which generates light. Each of the plurality of sub-pixels SP may generate light of a color (e.g., a particular color, or a particular wavelength band), such as red, green, blue, cyan, magenta, yellow, etc. Two or more sub-pixels among the plurality of sub-pixels SP may constitute one pixel PXL. In an embodiment, as shown in FIG. 1, three sub-pixels may constitute one pixel PXL, for example.

The gate driving circuit 120 may be connected to a plurality of sub-pixels SP (e.g., a plurality of sub-pixels SP arranged in the first direction DR1 as a whole) through the first to m-th gate lines GL1 to GLm. The first direction DR1 may be a direction from one side of the display panel 110 to an opposite side (e.g., from left to right), for example. The first direction DR1 may be a row direction, for example.

The gate driving circuit 120 may output gate signals (e.g., a gate signal at a turn-on level or a turn-off level) to the first to m-th gate lines GL1 to GLm in response to the gate control signal GCS. In an embodiment, the gate control signal GCS may include a start signal indicating the start of each frame, a horizontal synchronization signal for outputting gate signals in synchronization with the timing at which the data signals are applied.

In an embodiment, the first to m-th light emission control lines EL1 to ELm connected to the plurality of sub-pixels SP may be further disposed on the display panel 110. The first to m-th light emission control lines EL1 to ELm may be arranged to extend in the row direction in the display panel 110. The plurality of sub-pixels SP may be connected to the first to m-th light emission control lines (also referred to as emission control lines) EL1 to ELm. In the above embodiment, the gate driving circuit 120 may include a light-emitting control driver which controls the first to m-th light-emitting control lines EL1 to ELm. The light-emitting control driver may operate under the control of the controller 150.

The gate driving circuit 120 may be disposed on one side of the display panel 110. However, embodiments are not so limited. In an embodiment, the gate driving circuit 120 may be divided into two or more driving circuits that are physically and/or logically divided, and such driving circuits may be disposed on one side and an opposite side of the display panel 110 (e.g., an opposite side of a display panel 110 opposite to the one side), for example. As such, the gate driving circuit 120 may be disposed in the display panel 110 or in the periphery of the display panel 110 in various forms.

The data driver 130 may be connected to a plurality of sub-pixels SP (e.g., a plurality of sub-pixels SP arranged in the second direction DR2 as a whole) through the first to n-th data lines DL1 to DLn. The second direction DR2 may be a direction from one side (e.g., the lower side) to an opposite side (e.g., the upper side) of the display panel 110, for example. The second direction DR2 may be a column direction, for example.

The data driver 130 may receive the image data DATA and the data control signal DCS from the controller 150. The data driver 130 may operate in response to a data control signal DCS. In an embodiment, the data control signal DCS may include a source start pulse, a source shift clock, a source output enable signal, etc.

The data driver 130 may apply data signals having grayscale voltages corresponding to the image data DATA to the first through nth data lines DL1 through DLn using voltages (e.g., gamma voltage Vgamma) from the voltage generator 140. When a gate signal (e.g., a turn-on level gate signal) is applied to each of the first to m-th gate lines GL1 to GLm, data signals corresponding to the image data DATA may be applied to the data lines DL1 to DLm. Each of the plurality of sub-pixels SP may receive, in response to a gate signal (e.g., a gate signal at a turn-on level), a data signal applied at a corresponding timing. The plurality of sub-pixels SP may generate light corresponding to the input data signal. Accordingly, an image may be displayed on the display panel 110.

In an embodiment, gate driving circuit 120 and data driver 130 may each include complementary metal-oxide semiconductor (“CMOS”) circuit elements.

The voltage generator 140 may operate in response to a voltage control signal VCS from the controller 150. The voltage generator 140 may generate a plurality of voltages and provide the generated voltages to components of the display device 100. In an embodiment, the voltage generator 140 may receive an input voltage from the outside of the display device 100, for example. Voltage generator 140 may adjust (e.g., lower) the level of the received voltage and regulate the leveled voltage. The voltage generator 140 may generate a plurality of voltages.

The voltage generator 140 may generate, e.g., a first power supply voltage VDD, a second power supply voltage VSS, a gamma voltage Vgamma, or the like. The generated first and second power supply voltages VDD and VSS may be applied (e.g., commonly applied) to the plurality of sub-pixels SP. The first power supply voltage VDD may have a relatively high voltage level. The second power supply voltage VSS may have a lower voltage level than the first power supply voltage VDD. The generated gamma voltage Vgamma may be provided to the data driver 130. In other embodiments, the first power supply voltage VDD and/or the second power supply voltage VSS may be provided by an external device (e.g., a power management integrated circuit (“PMIC”)) of the display device 100.

Depending on the embodiment, the voltage generator 140 may generate a different voltage. In an embodiment, the voltage generator 140 may generate an initialization voltage that is applied (e.g., commonly applied) to the plurality of sub-pixels SP, for example. In an embodiment, in a sensing operation to sense electrical characteristics of the light-emitting element(s) and/or transistors of the plurality of sub-pixels SP, a preset reference voltage may be applied to the first to n-th data lines DL1 to DLn, and the voltage generator 140 may generate such a reference voltage, for example.

The controller 150 may control various operations of the display device 100. The controller 150 may receive the input image data IMG and the control signal CTRL for controlling the display thereof from the outside. The controller 150 may provide the gate control signal GCS, the data control signal DCS, the voltage control signal VCS, or the like in response to the received control signal CTRL.

The controller 150 may output the image data DATA by converting the input image data IMG to be suitable for the display device 100 or the display panel 110. In an embodiment, the controller 150 may output the image data DATA by aligning the input image data IMG to fit the sub-pixels SP in rows.

Two or more components of data driver 130, voltage generator 140, and controller 150 may be disposed (e.g., mounted) in one integrated circuit. As shown in FIG. 1, data driver 130, voltage generator 140, and controller 150 may be included in a driver integrated circuit DIC. In this case, the data driver 130, the voltage generator 140, and the controller 150 may be functionally distinct components within one driver integrated circuit DIC. In other embodiments, at least one of the data driver 130, the voltage generator 140, and the controller 150 may be disposed (e.g., mounted) in a driver integrated circuit DIC, and a remaining (the other) one may be disposed (e.g., mounted) and provided in a different integrated circuit than the driver integrated circuit DIC. The controller 150 may be a hardware component such as a circuitry that performs a predetermined function. The hardware component may include a field-programmable gate array (“FPGA”) or an application-specific integrated circuit (“ASIC”), for example.

The temperature sensor 160 senses a temperature (e.g., a temperature around it) and generate temperature data TEP indicative of the sensed temperature. In an embodiment, the temperature sensor 160 may be disposed on the display panel 110. In an embodiment, the temperature sensor 160 may be disposed next (adjacent) to the display panel 110 and/or a driver integrated circuit DIC. In an embodiment, the display device 100 may include two or more temperature sensors 160.

The controller 150 may control various operations of the display device 100 in response to the temperature data TEP. In an embodiment, the controller 150 may adjust the luminance of the image output from the display panel 110 in response to the temperature data TEP. In an embodiment, the controller 150 may adjust at least one of data signals input to the display panel 110, the first power supply voltage VDD, and the second power supply voltage VSS by controlling components such as the data driver 130 and/or the voltage generator 140, for example.

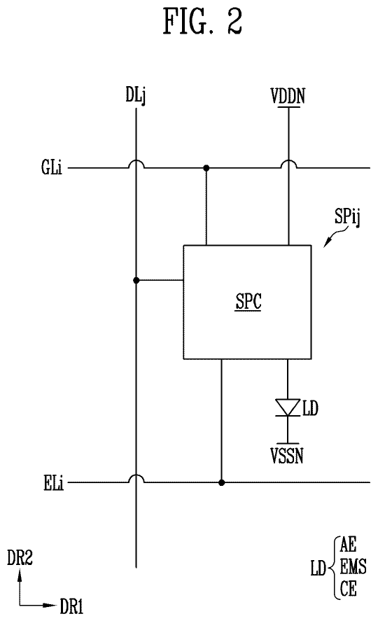

FIG. 2 is a block diagram showing an embodiment of any one of the sub-pixels SP of FIG. 1.

In FIG. 2, among the sub-pixels SP in FIG. 1, a sub-pixel SPij disposed in an i-th row (i is an integer greater than or equal to 1) and a j-th column (j is an integer greater or equal to 1), is shown.

Referring to FIG. 2, the sub-pixel SPij may include a sub-pixel circuit SPC and a light-emitting element LD.

The light-emitting element LD is connected between a first power supply voltage node VDDN and a second power supply voltage node VSSN. In this case, the first power supply voltage node VDDN is a node that transmits the first power supply Voltage VDD of FIG. 1, and the second power supply voltage node VSSN is a node which transmits the second power supply voltage VSS of FIG. 1.

The anode electrode AE of the light-emitting element LD is connected to the first power supply voltage node VDDN through the sub-pixel circuit SPC, and the cathode electrode CE of the light-emitting element LD may be connected to the second power supply voltage node VSSN. In an embodiment, the anode electrode AE of the light-emitting element LD may be connected to the first power supply voltage node VDDN via one or more transistors included in the sub-pixel circuit SPC, for example.

The sub-pixel circuit SPC may be connected to the i-th gate line GLi of the first to m-th gate lines GL1 to GLm of FIG. 1, the i-th light emission control line ELi of the first to m-th light-emitting control lines EL1 to ELm of FIG. 1, and the j-th data line DLj of the first to n-th data lines DL1 to DLn of FIG. 1. The sub-pixel circuit SPC controls the light-emitting element LD according to the signals received through these signal lines.

The sub-pixel circuit SPC may operate in response to a gate signal (or scan signal) received via the i-th gate line GLi. The i-th gate line GLi may include one or more sub-gate lines.

The sub-pixel circuit SPC may operate in response to a light emission control signal received via the i-th light emission control line ELi.

The sub-pixel circuit SPC may receive a data signal through the j-th data line DLj. In response to the light emission control signal received through the i-th light emission control line ELi, the sub-pixel circuit SPC may adjust the current flowing from the first power supply voltage node VDDN to the second power supply voltage node VSSN through the light-emitting element LD according to the stored voltage. Accordingly, the light-emitting element LD may generate light of a luminance corresponding to the data signal.

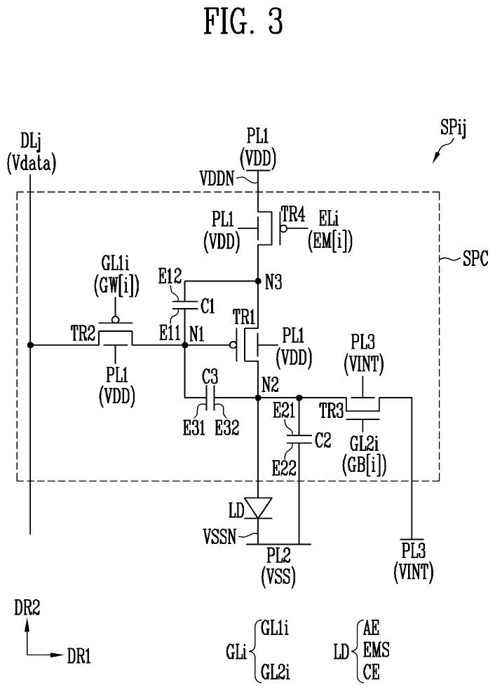

FIG. 3 is an equivalent circuit diagram of an embodiment of a sub-pixel SPij according to the disclosure.

The sub-pixel SPij in the embodiments of the disclosure may include a sub-pixel circuit SPC and a light-emitting element LD.

A sub-pixel circuit SPC may comprise two or more switching elements and one or more storage elements. In an embodiment, the switching element may be implemented as a transistor. In an embodiment, the storage element may be implemented as a capacitor.

Referring to FIG. 3, a sub-pixel circuit SPC in embodiments of the disclosure may include four transistors and three capacitors. In an embodiment, a sub-pixel circuit SPC in embodiments of the disclosure may include first to fourth transistors TR1 to TR4 and first to third capacitors C1 to C3, for example.

The first transistor TR1 may include a gate electrode electrically connected to the first node N1, a first electrode electrically connected to a second node N2, and a second electrode electrically connected to third node N3. The first transistor TR1 may include a body electrode electrically connected to the first power line PL1. The first electrode may be either a source electrode or a drain electrode (e.g., a drain electrode). The second electrode may be another of a source electrode and a drain electrode (e.g., a source electrode). The first transistor TR1 may control the magnitude of the current flowing through the light-emitting element LD according to the voltage applied to the first node N1.

The second transistor TR2 may switch an electrical connection between the j-th data line DLj and the first node N1 in response to the first scan signal GW[i] applied to the i-th first gate line GL1i. The second transistor TR2 may include a body electrode electrically connected to the first power line PL1. When the second transistor TR2 is turned on in response to the first scan signal GW[i] at the turn-on level (e.g., relatively low level), a data voltage Vdata or a voltage corresponding thereto may be applied to the first node N1. The i-th gate line GLi may include an i-th first gate line GL1i.

The third transistor TR3 may switch an electrical connection between the second node N2 and the third power line PL3 in response to the second scan signal GB[i] applied to the i-th second gate line GL2i. The third transistor TR3 may include a body electrode electrically connected to the third power line PL3. When the third transistor TR3 is turned on in response to the second scan signal GB[i] at the turn-on level (e.g., relatively high level), a third power supply voltage VINT or a voltage corresponding thereto may be applied to the second node N2. In an embodiment, the third power supply voltage VINT may be supplied from the voltage generator 140 described above (refer to FIG. 1). The i-th gate line GLi may include an i-th second gate line GL2i.

The fourth transistor TR4 may switch an electrical connection between the first power line PL1 and the third node N3 in response to the i-th light emission control signal EM[i] applied to the i-th light emission control line ELi. The fourth transistor TR4 may include a body electrode electrically connected to the first power line PL1. When the fourth transistor TR4 is turned on in response to the i-th light emission control signal EM[i] at the turn-on level (e.g., relatively low level), the first power supply voltage VDD may be applied to the third node N3. The fourth transistor TR4 may be electrically connected to the first power line PL1 through the first power supply voltage node VDDN. A first power supply voltage VDD may be applied to the first power line PL1.

The first capacitor C1 may maintain a potential difference between the first node N1 and the third node N3. The first capacitor C1 may include a first electrode E11 electrically connected to the first node N1 and a second electrode E12 electrically connected to the third node N3. In an embodiment, the first electrode E11 and the second electrode E12 may be disposed in the same layer. In another embodiments, the first electrode E11 and the second electrode E12 may be disposed in different layers.

The second capacitor C2 may mitigate (e.g., minimize) voltage variation of the second node N2. In an embodiment, the second capacitor C2 may be configured in parallel with the light-emitting element LD. The second capacitor C2 may include a first electrode E21 electrically connected to the second node N2 and a second electrode E22 electrically connected to the second power line (also referred to as a power line) PL2. The first electrode E21 and the second electrode E22 may be disposed in the same layer. The second capacitor C2 may be physically distinguished from the parasitic capacitance of the light-emitting element LD itself, which is formed by the anode electrode AE and the cathode electrode CE being disposed in different layers with the light-emitting structure EMS interposed therebetween. In the embodiments of the disclosure, the capacitance of the second capacitor C2 may be greater than the capacitance between the anode and the cathode of the light-emitting element LD.

The third capacitor C3 may maintain a potential difference between the first node N1 and the second node N2. The third capacitor C3 may include a first electrode E31 electrically connected to the first node N1 and a second electrode E32 electrically connected to the second node N2. In an embodiment, the first electrode E31 and the second electrode E32 of the third capacitor C3 may be disposed in the same layer as each other. In another embodiment, the first electrode E31 and the second electrode E32 of the third capacitor C3 may be disposed in different layers.

The light-emitting element LD may include a first electrode (e.g., an anode electrode AE) electrically connected to the second node N2, a second electrode (e.g., a cathode electrode CE) electrically connected to a second power line PL2, and a light-emitting structure EMS disposed between the anode electrode AE and the cathode electrode CE. The cathode electrode CE may be electrically connected to the second power line PL2 via a second power supply voltage node VSSN. A second power supply voltage (also referred to as a constant voltage) VSS may be applied to the second power line PL2.

Each of the first to fourth transistors TR1 to TR4 may be either a transistor including a P-type semiconductor or a transistor including an N-type semiconductor. In an embodiment, the first transistor TR1, the second transistor TR2, and the fourth transistor TR4 may be implemented as transistors including a P-type semiconductor. In the above embodiment, the third transistor TR3 may be implemented as a transistor including an N-type semiconductor. However, embodiments of the disclosure are not limited thereto. In an embodiment, at least one of the first transistor TR1, the second transistor TR2, and the fourth transistor TR4 may be implemented as a transistor including an N-type semiconductor, or the third transistor TR3 may be implemented as a transistor including a P-type semiconductor, for example.

A transistor including a P-type semiconductor may be turned on in response to a low-level signal and turned off in response to a high-level signal. A transistor including an N-type semiconductor may be turned on in response to a high-level signal and turned off in response to a low-level signal.

In an embodiment, each of the first to fourth transistors TR1 to TR4 may be implemented as a transistor including a body electrode. However, in an embodiment, at least one of the first to fourth transistors TR1 to TR4 may be implemented as a transistor that does not include a body electrode.

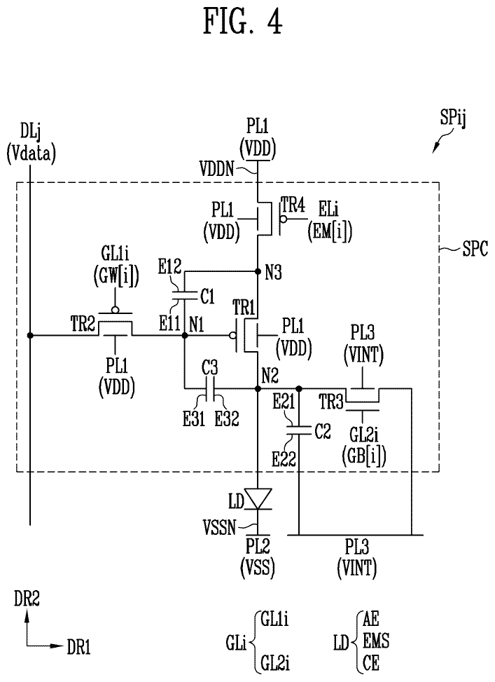

FIG. 4 is an equivalent circuit diagram of an embodiment of a sub-pixel SPij according to the disclosure.

Compared with FIG. 3, the second electrode E22 of the second capacitor C2 may be electrically connected to the third power line (also referred to as a power line) PL3 to which the third power supply voltage (also referred to as a constant voltage) VINT is applied. The second capacitor C2 may perform a function of maintaining the voltage of the second node N2.

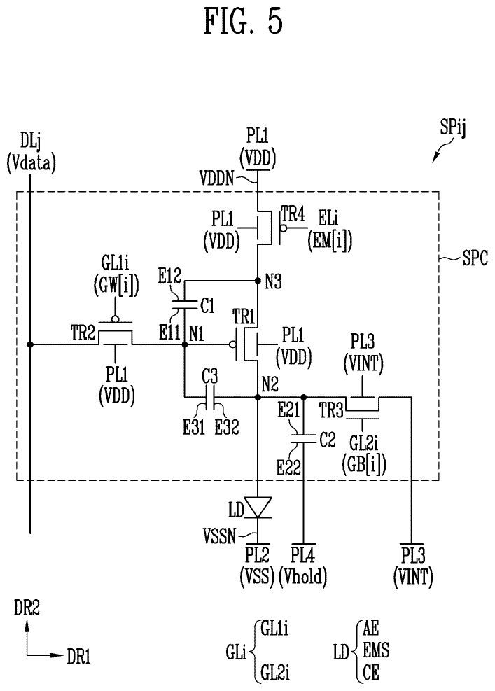

FIG. 5 is an equivalent circuit diagram of an embodiment of a sub-pixel SPij according to the disclosure.

Compared with FIGS. 3 and 4, the second electrode E22 of the second capacitor C2 may be electrically connected to the fourth power line (also referred to as a power line) PL4 to which fourth power supply voltage (also referred to as a constant voltage) Vhold is applied. The second capacitor C2 may perform a function of maintaining the voltage of the second node N2.

A fourth power supply voltage Vhold may be applied to the fourth power line PL4. A fourth power supply voltage Vhold may be supplied from the voltage generator 140 described above (refer to FIG. 1). In an embodiment, the fourth power supply voltage Vhold may be the same as the first power supply voltage VDD. The fourth power line PL4 may be the same as or electrically connected to the first power line PL1.

In an embodiment, the fourth power supply voltage Vhold may be different from all of the first power supply voltage VDD, the second power supply voltage VSS, and the third power supply voltage VINT.

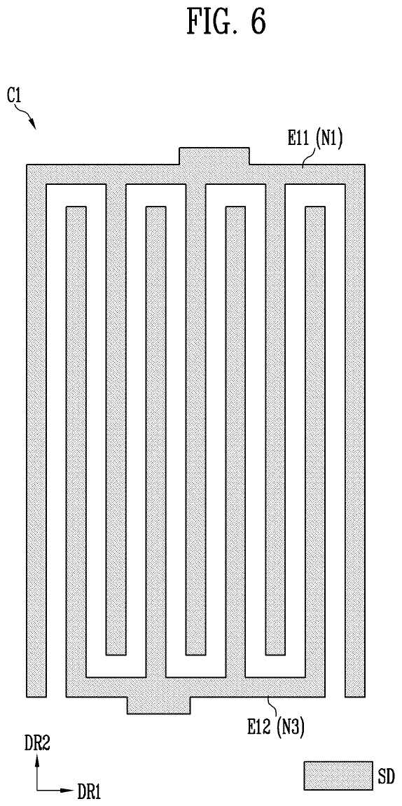

FIG. 6 is an embodiment of the first capacitor C1.

Referring to FIG. 6, the first electrode E11 and the second electrode E12 of the first capacitor C1 may include the same electrode layer SD. Each of the first electrode E11 and the second electrode E12 of the first capacitor C1 may be disposed in the same plane formed by the first direction DR1 and the second direction DR2.

The first electrode E11 of the first capacitor C1 may be electrically connected to the first node N1. The second electrode E12 may be electrically connected to the third node N3.

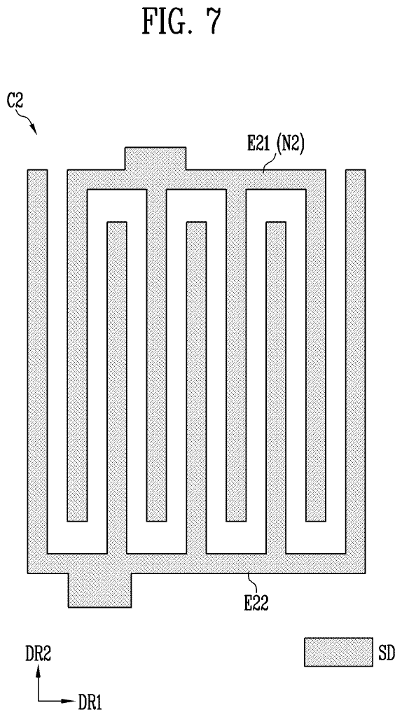

FIG. 7 is an embodiment of the second capacitor C2.

Referring to FIG. 7, the first electrode E21 and the second electrode E22 of the second capacitor C2 may include the same electrode layer SD. Each of the first electrode E21 and the second electrode E22 of the second capacitor C2 may be disposed on the same plane formed by the first direction DR1 and the second direction DR2.

The first electrode E21 of the second capacitor C2 may be electrically connected to the second node N2.

With further reference to FIG. 6 described above, each of the first electrode E11 and the second electrode E12 of the first capacitor C1 may be disposed in the same layer as each of the first electrodes E21 and the second electrodes E22 of the second capacitor C2. However, embodiments of the disclosure are not limited thereto, and each of the first electrode E11 and the second electrode E12 of the first capacitor C1 may be disposed in a different layer from each of the first electrodes E21 and the second electrodes E22 of the second capacitor C2.

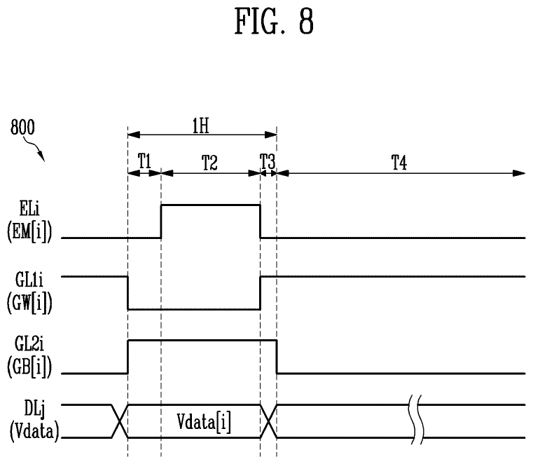

FIG. 8 is an embodiment of a method 800 of driving a sub-pixel according to the disclosure.

The driving method 800 of the sub-pixel may be also referred to as a driving method 800 of a display device or a driving method 800 of an electronic device.

Referring to FIG. 8, a horizontal period 1H (or a predetermined horizontal period) during which a sub-pixel is driven may be divided into a first period T1, a second period T2, a third period T3, and a fourth period T4.

The data driver 130 (refer to FIG. 1) may supply the data voltage Vdata[i] supplied to the i-th pixel row to the j-th data line DLj during the first period T1 to the third period T3.

The gate driving circuit 120 (refer to FIG. 1) may supply the first scan signal GW[i] at the turn-on level to the i-th first gate line GL1i during the first period T1 and the second period T2. The gate driving circuit 120 may supply the first scan signal GW[i] at the turn-off level to the i-th first gate line GL1i during the third period T3 and the fourth period T4. In an embodiment, the first scan signal GW[i] at the turn-on level may be at a relatively low level. The first scan signal GW[i] at the turn-off level may be at a relatively high level.

The gate driving circuit 120 (refer to FIG. 1) may supply the second scan signal GB[i] at the turn-on level to the i-th second gate line GL2i during the first to third periods T1 to T3. The gate driving circuit 120 may supply the second scan signal GB[i] at the turn-off level to the i-th second gate line GL2i during the fourth period T4. In an embodiment, the second scan signal GB[i] at the turn-on level may be at a relatively high level. The second scan signal GB[i] at the turn-off level may be at a relatively low level.

The gate driving circuit 120 (refer to FIG. 1) may supply the i-th light emission control signal EM[i] at the turn-off level to the i-th light emission control line ELi during the second period T2. The gate driving circuit 120 may supply the i-th light emission control signal EM[i] at the turn-on level to the i-th light emission control line ELi during the first period T1, the third period T3, and the fourth period T4. The i-th light emission control signal EM[i] at the turn-on level may be at a relatively low level. The i-th light emission control signal EM[i] at the turn-off level may be at a relatively high level.

The first period T1 may be also referred to as a “initialization period”. The second period T2 may be also referred to as a “data write and threshold voltage compensation period”. The third period T3 may be also referred to as a “luminance control period”. The fourth period T4 may be also referred to as a “emission period”. Hereinafter, the first to fourth periods T1 to T4 will be described in detail.

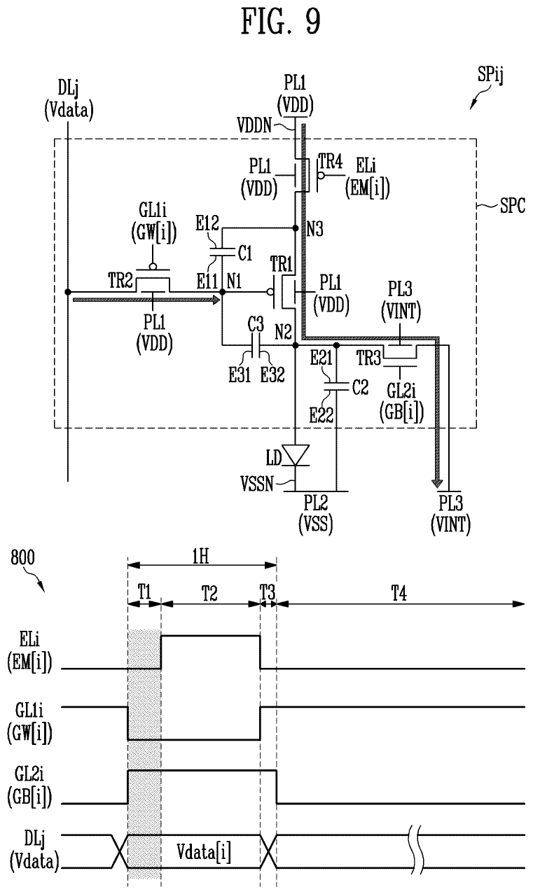

FIGS. 9 to 12 are diagrams for explaining the driving method of FIG. 8 with respect to the sub-pixel SPij of FIG. 3.

For convenience of description, the driving method 800 is described with reference to the sub-pixel SPij in FIG. 3. However, embodiments of the disclosure are not limited thereto, and the driving method 800 of FIG. 8 may be similarly applied to the sub-pixel SPij of FIG. 4 and the sub-pixel SPij of FIG. 5.

FIG. 9 is a diagram illustrating a first period T1 of the driving method 800.

Referring to FIG. 9, the first scan signal GW[i] at the turn-on level may be supplied to the i-th first gate line GL1i during the first period T1. A second scan signal GB[i] at the turn-on level may be supplied to the i-th second gate line GL2i. During the first period T1, a turn-on level of the i-th light emission control signal (also referred to as an emission control signal) EM[i] may be supplied to the i-th light emission control line ELi. The first transistor TR1, the second transistor TR2, the third transistor TR3, and the fourth transistor TR4 may be turned on.

When the first scan signal GW[i] at the turn-on level is supplied to the i-th first gate line GL1i, the second transistor TR2 may be turned on. When the second transistor TR2 is turned on, the data voltage Vdata[i] may be supplied to the first node N1 from the j-th data line DLj.

The first capacitor C1 may be initialized by the data voltage Vdata[i] and the first power supply voltage VDD. During the first period T1, the first capacitor C1 may charge a voltage corresponding to a voltage difference between the data voltage Vdata[i] and the first power supply voltage VDD irrespective of a voltage charged in a previous period (or a previous frame period).

When the second scan signal GB[i] at the turn-on level is supplied to the i-th second gate line GL2i, the third transistor TR3 may be turned on. When the third transistor TR3 is turned on, the third power supply voltage VINT may be supplied to the second node N2. When the third power supply voltage VINT is supplied to the second node N2, the light-emitting element LD may be initialized. When the third power supply voltage VINT is supplied to the second node N2, the voltage of the anode electrode of the light-emitting element LD may be initialized to the third power supply voltage VINT.

The second capacitor C2 may be initialized by the third power supply voltage VINT. In an embodiment, during the first period T1, the second capacitor C2 may charge a voltage corresponding to a voltage difference between the third power supply voltage VINT and the second power supply voltage VSS irrespective of a voltage charged in a previous period (or a previous frame period), for example.

The third capacitor C3 may be initialized by the data voltage Vdata[i] supplied to the first node N1 and the third power supply voltage VINT supplied to the second node N2. In an embodiment, during the first period T1, the third capacitor C3 may charge a voltage corresponding to the data voltage Vdata[i] and the third power supply voltage VINT regardless of a voltage charged in a previous period (or a previous frame period), for example.

During the first period T1, the current supplied from the first transistor TR1 may flow in the direction of the third power line PL3 via the third transistor TR3. During the first period T1, the light-emitting element LD may remain in a non-light-emitting state.

The voltage of the first node N1 in the first period T1 may be equal to the data voltage Vdata[i]. The voltage of the second node N2 may be equal to the third power supply voltage VINT. The voltage of the third node N3 may be equal to the first power supply voltage VDD.

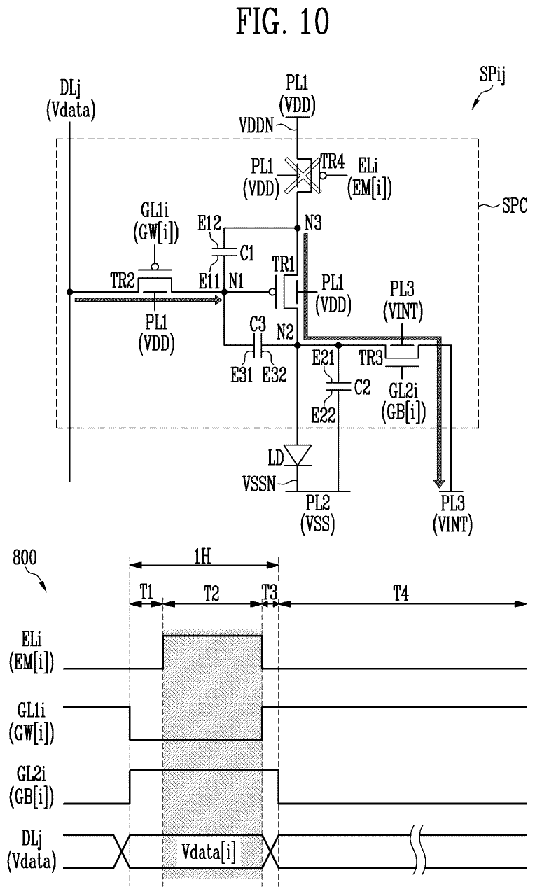

FIG. 10 is a diagram illustrating a second period T2 of the driving method 800.

Referring to FIG. 10, during the second period T2, the second transistor TR2 may be maintained in a turn-on state in response to the first scan signal GW[i] at the turn-on level supplied to the i-th first gate line GL1i, and the third transistor TR3 may be maintained in the turn-on state, in response to the second scan signal GB[i] at a turn-on level, supplied to the i-th second gate line GL2i.

During the second period T2, the fourth transistor TR4 may be turned off in response to the light control signal EM[i] at the turn-off level supplied to the i-th light emission control line ELi. When the fourth transistor TR4 is turned off, the first power line PL1 and the third node N3 may be electrically isolated.

When the second transistor TR2 is set to the turn-on state during the second period T2, the first node N1 may be electrically connected to the j-th data line DLj to supply the data voltage Vdata[i]. During the second period T2, the third node N3 may fall from the first power supply voltage VDD in the floating state to the voltage of Equation 1 as follows.

$$VN ( 3 ) = Vdata [ i ] + \vert Vth\_TR 1 \vert \qquad [ Equation 1 ]$$

In Equation 1, “VN(3)” refers to the voltage of the third node N3. “Vdata[i]” denotes the data voltage Vdata[i]. “|Vth_TR1|” denotes the absolute value of the threshold voltage of the first transistor TR1.

During the second period T2, a voltage corresponding to the threshold voltage of the first transistor TR1 may be stored in the first capacitor C1.

During the second period T2, the fourth transistor TR4 is set to the turn-off state, and the current supplied from the third node N3 to the second node N2 via the first transistor TR1 may flow in the direction of the third power line PL3 via the third transistor TR3. During the second period T2, the light-emitting element LD may remain in a non-light-emitting state.

The voltage of the first node N1 in the second period T2 may be the data voltage Vdata[i]. The voltage of the second node N2 may be a third power supply voltage VINT.

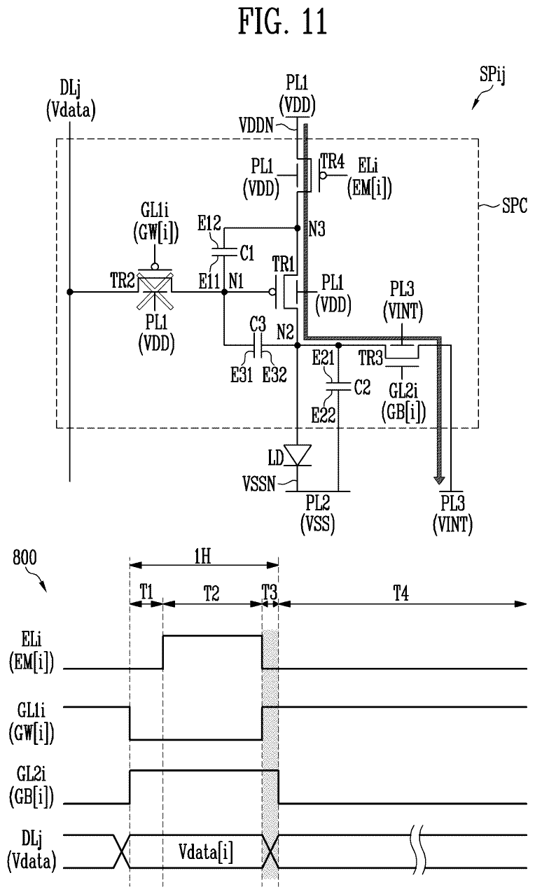

FIG. 11 is a diagram illustrating a third period T3 of the driving method 800.

Referring to FIG. 11, during the third period T3, the i-th light emission control line ELi is supplied with the i-th light emission control signal EM[i] at the turn-on level, and the fourth transistor TR4 may be set to the turn-on state. During the third period T3, the first scan signal GW[i] at the turn-off level is applied to the i-th first gate line GL1i, and the second transistor TR2 may be set to the turn-off state. During the third period T3, the second scan signal GB[i] at the turn-on level is supplied to the i-th second gate line GL2i, and the third transistor TR3 may remain in the turn-on state.

When the third transistor TR3 is turned on in the third period T3, the first transistor TR1 may control the amount of current supplied from the first power line PL1 to the second node N2 in response to the voltage of the first node N1. When the third transistor TR3 is set to the turn-on state, the current supplied to the second node N2 may be directed to the third power line PL3. During the third period T3, the light-emitting element LD is set to a non-light-emitting state, so that the grayscale expressive power of the display device 100 (refer to FIG. 1) may be improved.

In detail, the voltage of the second node N2 may be raised to a voltage higher than a desired voltage through the second period T2, and thus unnecessary current may be supplied to the light-emitting element LD. In an embodiment, the light-emitting element LD may emit light temporarily even when the black grayscale is implemented in the sub-pixel SPij, for example. Therefore, in the embodiment of the disclosure, the current supplied from the first transistor TR1 is supplied to the third power line PL3 during the third period T3, so that the grayscale power of the display device 100 (refer to FIG. 1) may be improved.

In the third period T3, the voltage of the first node N1 may rise to the first power supply voltage VDD. Accordingly, the voltage change amount of the first node N1 may be expressed as Equation 2.

$$VN ( 1 ) = Vdata [ i ] + αΔ Vs \qquad [ Equation 2 ]$$

In Equation 2, “VN(1)” refers to the voltage of the first node N1. “Vdata[i]” denotes the data voltage Vdata[i]. “ΔVs” may denote a voltage change amount of the third node N3. “α” refers to the ratio at which the voltage change of the third node N3 is reflected in the voltage change of first node N1.

“ΔVs” may be calculated as shown in Equation 3 below.

$$Δ Vs = VDD - ( Vdata [ i ] + \vert Vth\_TR 1 \vert ) \qquad [ Equation 3 ]$$

“α” may be calculated as shown in Equation 4 below.

$$α = \frac{c 1}{c 1 + c 3} \qquad [ Equation 4 ]$$

In Equation 4, “c1” refers to the storage capacity of the first capacitor C1. “c3” denotes the storage capacity of the third capacitor C3.

The voltage of the second node N2 in the third period T3 may be equal to the third power supply voltage VINT.

As the level of the first scan signal GW[i] transitions from the turn-on level to the turn-off level while proceeding from the second period T2 to the third period T3, and the voltage applied to the j-th data line DLj fluctuates, a ripple voltage may be applied to the second node N2. The second capacitor C2 may mitigate (e.g., minimize) the variation of the voltage of the second node N2 from the third power supply voltage VINT due to the ripple voltage. Accordingly, the voltage of the second node N2 may be maintained at the third power supply voltage VINT.

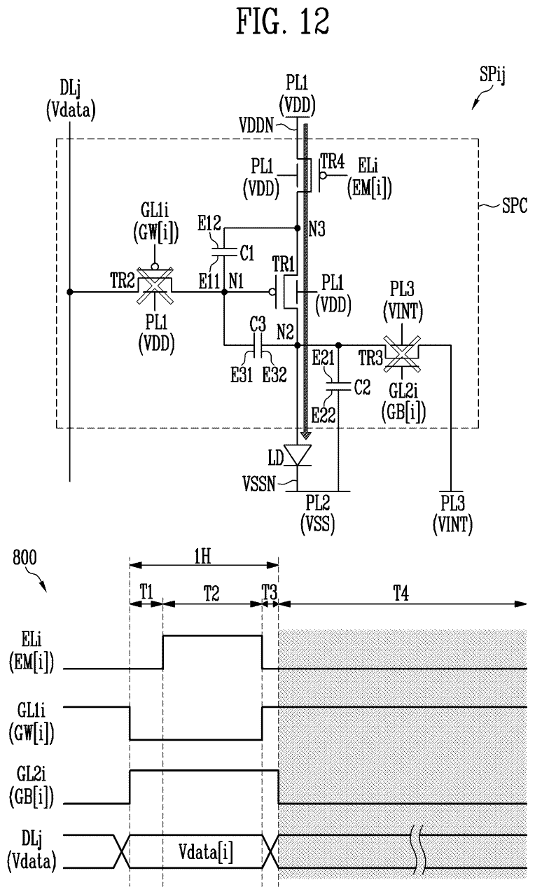

Referring to FIG. 12, during the fourth period T4, the second scan signal GB[i] at the turn-off level is applied to the i-th second gate line GL2i, and the third transistor TR3 may be turned off. During the fourth period T4, the first scan signal GW[i] at the turn-off level is applied to the i-th first gate line GL1i, and the second transistor TR2 may be in the turn-off state. During the fourth period T4, the i-th emission control signal EM[i] at the turn-on level is applied to the i-th light emission control line ELi, and the fourth transistor TR4 may be in the turn-on state.

FIG. 12 is a diagram illustrating a fourth period T4 of the driving method 800.

In the fourth period T4, the first transistor TR1 may control the amount of current supplied from the first power supply voltage node VDDN to the second power supply voltage node VSSN via the light-emitting element LD in response to the voltage of the first node N1. During the fourth period T4, the light-emitting element LD may generate light having a luminance corresponding to the amount of driving current supplied from the first transistor TR1.

During the fourth period T4, the voltage of the second node N2 may be changed from the third power supply voltage VINT to a predetermined voltage. The voltage change amount of the second node N2 during the fourth period T4 is as shown in Equation 5 below.

$$Δ {V}_{A} = {V}_{{A}^{′}} - VINT \qquad [ Equation 5 ]$$

In Equation 5, “ΔV_{A}” refers to the amount of voltage change of the second node N2. “V_{A}′” refers to the voltage of the second node N2 in the fourth period T4. “VINT” refers to the third power supply voltage VINT, and may correspond to the voltage of the second node N2 in the third period T3.

Due to the coupling phenomenon of the third capacitor C3, the voltage of the first node N1 may fluctuate as shown in Equation 6 below.

$$VN ( 1 ) = Vdata [ i ] + αΔ Vs \neq β Δ {V}_{A} \qquad [ Equation 6 ]$$

In Equation 6, “VN(1)” refers to the voltage of the first node N1. “Vdata[i]+αΔVs” corresponds to the voltage of the first node N1 in the third period T3. “β” refers to the ratio at which the voltage change of the second node N2 is reflected in the voltage change of first node N1. “ΔV_{A}” is the same as calculated in Equation 5.

“β” may be calculated as shown in Equation 7 below.

$$β = \frac{c 3}{c 1 + c 3} \qquad [ Equation 7 ]$$

In Equation 7, “c1” refers to the storage capacity of the first capacitor C1. “c3” denotes the storage capacity of the third capacitor C3.

Rewriting Equation 6 using Equations 4, 5, and 7, the voltage of the first node N1 may be expressed as Equation 8 below.

$$VN ( 1 ) = Vdata [ i ] + \frac{c 1}{c 1 + c 3} \text{?} VDD - ( Vdata [ i ] + \text{?} Vth\_TR1 \text{?} + \frac{c 1}{c 1 + c 3} ( \text{?} - VINT ) \qquad [ Equation 8 ]$$

$$\text{?} \text{indicates text missing or illegible when filed}$$

The voltage difference between the source electrode and the gate electrode of the first transistor TR1 in the fourth period T4 may be expressed as Equation 9 below.

$$Vsg = VDD - [ Vdata [ i ] + \frac{c 1}{c 1 + c 3} \text{?} VDD - ( Vdata [ i ] + \text{?} Vth\_TR1 \text{?} + \frac{c 1}{c 1 + c 3} ( \text{?} VINT ) ] \qquad [ Equation 9 ]$$

$$\text{?} \text{indicates text missing or illegible when filed}$$

In Equation 9, “Vsg” may correspond to a voltage difference between the source electrode and the gate electrode of the first transistor TR1. The voltage of the source electrode may be equal to the first power supply voltage VDD. The voltage of the gate electrode may be the same as “VN(1)”, which is the voltage of the first node in Equation 8.

The threshold voltage of the first transistor TR1 may be set differently depending on a voltage difference between the voltage of the body electrode and the voltage of the source electrode of the first transistor TR1. Assuming that the first power supply voltage VDD is set to 8 volts (V), the voltage of the body electrode of the first transistor TR1 may be set to 8 V during the second period T2. The voltage of the source electrode (or the third node N3) of the first transistor TR1 may be set to a voltage lower than the voltage of the body electrode. In an embodiment, assuming that the voltage of the third node N3 is set to 4 V, the voltage difference between the voltage of the body electrode of the first transistor TR1 and the voltage of the source electrode may be set to 4 V, for example. Accordingly, the first transistor TR1 may have the first threshold voltage in the second period T2. In a second period T2, the first threshold voltage may be compensated. The absolute value of the first threshold voltage may be represented by |Vth_TR1| described in Equation 1.

Next, the voltage of the third node N3 during the fourth period T4 may be the first power supply voltage VDD. The voltage of the body electrode and the voltage of the source electrode of the first transistor TR1 may be set to be the same in the fourth period T4, and the threshold voltage of the first transistor T1 may be the second threshold voltage in the fourth period. The second threshold voltage may be different from the first threshold voltage. The absolute value of the second threshold voltage may be denoted by |Vth_TR1′].

The magnitude of the driving current flowing through the light-emitting element LD in the first transistor TR1 in the fourth period T4 is as shown in Equation 10 below.

$${I}_{LD} = \frac{1}{2} μ Cox \frac{W}{L} {( Vsg - \vert {Vth\_TR1}^{′} \vert )}^{2} \qquad [ Equation 10 ]$$

In Equation 10, “I_{LD}” refers to the magnitude of the driving current flowing through a light-emitting element LD. “μ” refers to the electron mobility of the first transistor TR1. “Cox” refers to the oxide capacitance of the first transistor TR1. “W” refers to the channel width of the first transistor TR1. “L” refers to the channel length of the first transistor TR1. “Vsg” is the same as calculated in Equation 9. “|Vth_TR1′]” may refer to the threshold voltage of the first transistor TR1 in the fourth period T4 as the second threshold voltage.

When Equation 10 is solved, it is as shown in Equation 11 below.

$$\text{?} = \frac{1}{2} μ Cox \frac{W}{L} \{ \frac{c 1}{c 1 + c 3} ( VDD - ( Vdata [ i ] ) + \frac{c 1}{c 1 + c 3} \vert Vth\_TR1 \vert - \frac{c 1}{c 1 + c 3} ( \text{?} - VINT ) - \vert {Vth\_TR1}^{′} \vert \} \text{?} \qquad [ Equation 11 ]$$

$$\text{?} \text{indicates text missing or illegible when filed}$$

Referring to Equation 11, the data voltage Vdata[i] may be reflected in the driving current (e.g., I_{LD} in Equation 11) as a value multiplied by the ratio of the capacitances of the first and third capacitors C1 and C3 (e.g., c3/(c1+c3) in Equation 11). When the data voltage Vdata[i] is reflected in the driving current corresponding to the ratio of the capacitance of the capacitors, the range of the data voltage may be relatively widened.

Referring further to FIG. 1, when converting the input image data IMG into image data DATA, the controller 150 may generate the image data DATA based on the capacitance of the first capacitor C1 (e.g., c1 in Equation 11) and the capacitance of the third capacitor C3 (e.g., c3 in Equation 11). The data driver 130 may generate a data voltage Vdata corresponding to the input image data DATA.

In an embodiment, the range of the data voltage is set to be relatively small when the data voltage Vdata[i] is directly reflected in the driving current (or the coefficient multiplied by the data voltage Vdata[i] equal to or greater than 1). In this case, it is relatively difficult to implement various gray levels using a relatively small range of data voltages, and thus to stably implement a predetermined gray level. When the range in which the data voltage may be set is widened by multiplying the data voltage by the value of a smaller coefficient as in the application, a preset grayscale may be stably implemented.

In addition, the absolute value of the threshold voltage of the first transistor TR1 (e.g., |Vth_TR1| in Equation 11) may be reflected in the driving current corresponding to the ratio of the capacities of the first and third capacitors C1 and C3 (e.g., c1/(c1+c3) in Equation 11). In this case, the influence of the threshold voltage of the first transistor TR1 may be mitigated.

The difference between the voltage of the second node N2 and the third power supply voltage VINT (e.g., V_{A}′−VINT in Equation 11) may be reflected in the driving current corresponding to the ratio of the capacities of the first and third capacitors C1 and C3 (e.g., c3/(c1+c3) in Equation 11). In this case, the influence of the voltage fluctuation of the second node N2 is mitigated, so that visibility may be improved.

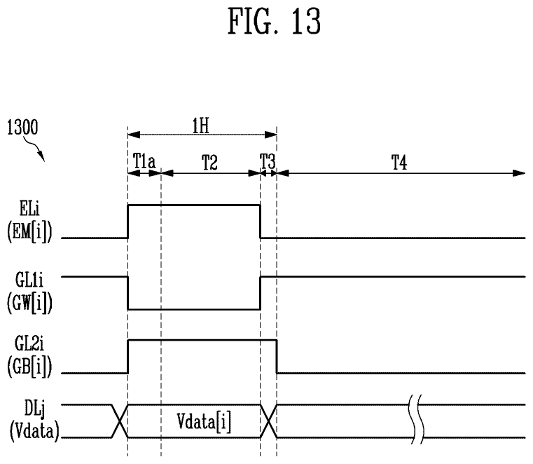

FIG. 13 is an embodiment of a method 1300 of driving a sub-pixel according to the disclosure.

The sub-pixel driving method 1300 may be also referred to as a driving method 1300 of a display device or a driving method 1300 of an electronic device.

Referring to FIG. 13, a horizontal period 1H (or a predetermined horizontal period) during which the sub-pixel SPij is driven may include a first period T1a, a second period T2, and a third period T3.

The driving method 1300 of FIG. 13 may further compensate the threshold voltage of the first transistor TR1 in the first period T1a when compared with the driving method 800 of FIG. 8.

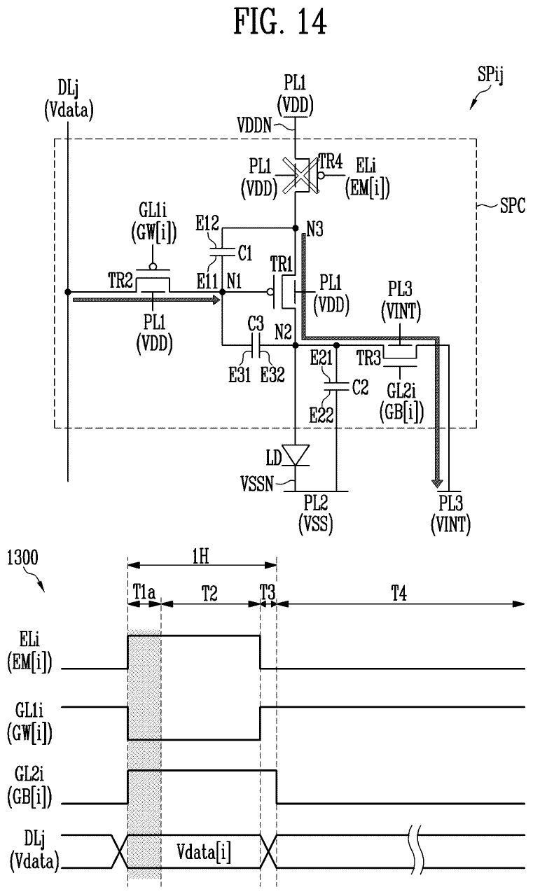

FIGS. 14 to 17 are diagrams for explaining the driving method 1300 of FIG. 13 with respect to the sub-pixels of FIG. 3 in parallel.

For convenience of description, the driving method 1300 is described with reference to the sub-pixel SPij in FIG. 3. However, embodiments of the disclosure are not limited thereto, and the driving method 1300 of FIG. 13 may be similarly applied to the sub-pixel SPij of FIG. 4 and the sub-pixel SPij of FIG. 5.

FIG. 14 is a diagram illustrating a first period Ta of the driving method 1300.

Referring to FIG. 14, the first scan signal GW[i] at the turn-on level may be supplied to the i-th first gate line GL1i during the first period T1a. A second scan signal GB[i] at the turn-on level may be supplied to the i-th second gate line GL2i. During the first period T1a, the i-th emission control signal EM[i] at the turn-off level may be supplied to the i-th light emission control line ELi. The first transistor TR1, the second transistor TR2, and the third transistor TR3 may be turned on.

When the first scan signal GW[i] at the turn-on level is supplied to the i-th first gate line GL1i, the second transistor TR2 may be turned on. When the second transistor TR2 is turned on, the data voltage Vdata[i] may be supplied to the first node N1 from the j-th data line DLj.

The first capacitor C1 may charge a voltage corresponding to a voltage difference between the data voltage Vdata[i] and the first power supply voltage VDD by the first power supply voltage VDD applied to the third node N3 in the fourth period T4 of the immediately preceding frame and the data voltage Vdata[i] applied during the first period T1.

When the second scan signal GB[i] at the turn-on level is supplied to the i-th second gate line GL2i, the third transistor TR3 may be turned on. When the third transistor TR3 is turned on, the third power supply voltage VINT may be supplied to the second node N2. When the third power supply voltage VINT is supplied to the second node N2, the light-emitting element LD may be initialized. When the third power supply voltage VINT is supplied to the second node N2, the voltage of the anode electrode of the light-emitting element LD may be initialized to the third power supply voltage VINT.

The second capacitor C2 may be initialized by the third power supply voltage VINT. In an embodiment, during the first period T1, the second capacitor C2 may charge a voltage corresponding to a voltage difference between the third power supply voltage VINT and the second power supply voltage VSS irrespective of a voltage charged in a previous period (or a previous frame period), for example.

The third capacitor C3 may be initialized by the data voltage Vdata[i] supplied to the first node N1 and the third power supply voltage VINT supplied to the second node N2. During the first period T1, the third capacitor C3 may charge a voltage corresponding to the data voltage Vdata[i] and the third power supply voltage VINT irrespective of the voltage charged in the previous period (or the previous frame period).

During the first period T1, the current supplied from the first transistor TR1 may flow in the direction of the third power line PL3 via the third transistor TR3. During the first period T1, the light-emitting element LD may remain in a non-light-emitting state.

The voltage of the first node N1 in the first period T1 may be equal to the data voltage Vdata[i]. The voltage of the second node N2 may be equal to the third power supply voltage VINT.

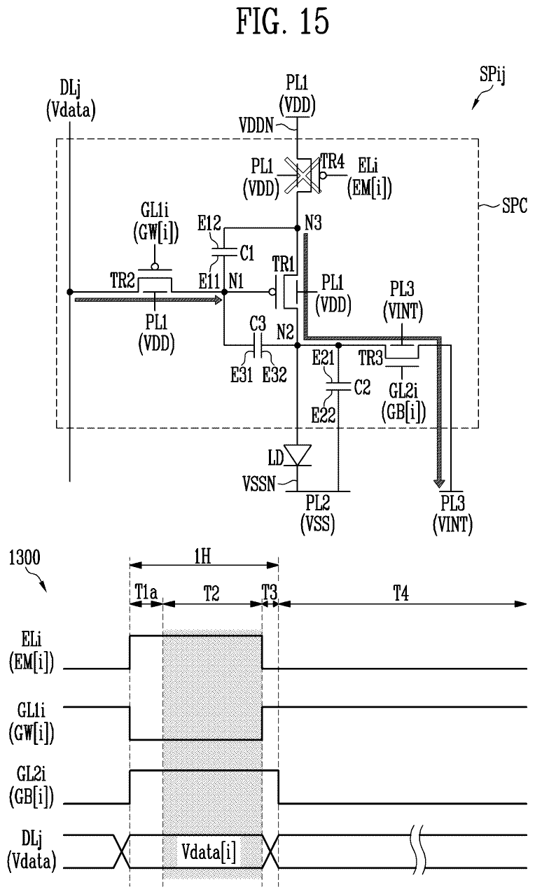

FIG. 15 is a diagram illustrating a second period T2 of the driving method 1300.

Referring to FIG. 15, during the second period T2, the second transistor TR2 may be maintained in a turn-on state in response to the first scan signal GW[i] at the turn-on level supplied to the i-th first gate line GL1i, and the third transistor TR3 may be maintained in the turn-on state, in response to the second scan signal GB[i] at a turn-on level, supplied to the i-th second gate line GL2i.

During the second period T2, the fourth transistor TR4 may remain in the turn-off state in response to the i-th light emission control signal EM[i] at the turn-off level supplied to the i-th light emission control line ELi.

When the second transistor TR2 is set to the turn-on state during the second period T2, the first node N1 may be electrically connected to the j-th data line DLj to supply the data voltage Vdata[i]. During the second period T2, the third node N3 may drop from the first power supply voltage VDD in the floating state to a voltage of Equation 12 as follows.

$$VN ( 3 ) = Vdata [ i ] + \vert Vth\_TR 1 \vert \qquad [ Equation 12 ]$$

In Equation 12, “VN(3)” refers to the voltage of the third node N3. “Vdata[i]” denotes the data voltage Vdata[i]. “|Vth_TR1|” denotes the absolute value of the threshold voltage of the first transistor TR1. Equation 12 is the same as Equation 1.

During the second period T2, a voltage corresponding to the threshold voltage of the first transistor TR1 may be stored in the first capacitor C1.

During the second period T2, the third transistor TR3 is set to the turn-on state, and the current supplied from the third node N3 to the second node N2 via the first transistor TR1 may flow in the direction of the third power line PL3 via the third transistor TR2. During the second period T2, the light-emitting element LD may remain in a non-light-emitting state.

The voltage of the first node N1 in the second period T2 may be the data voltage Vdata[i]. The voltage of the second node N2 may be a third power supply voltage VINT.

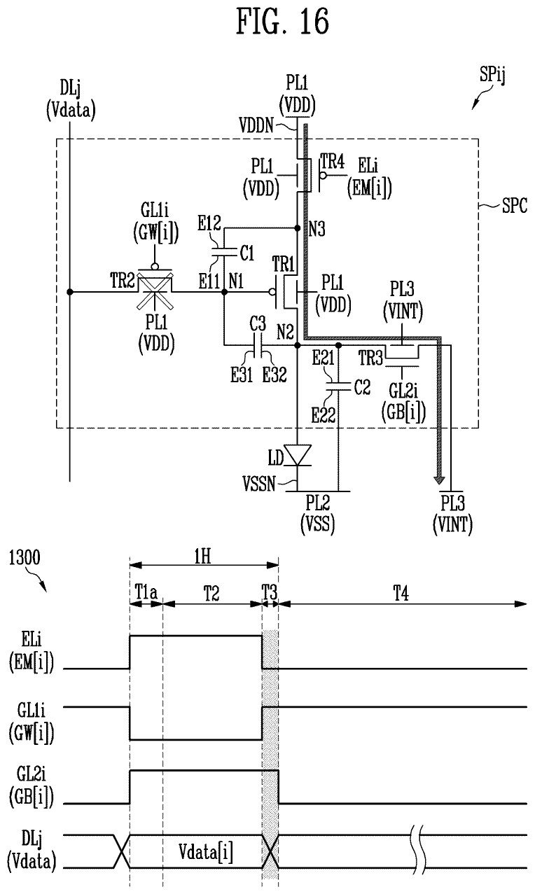

FIG. 16 is a diagram illustrating a third period T3 of the driving method 1300.

Referring to FIG. 16, during the third period T3, the i-th light emission control line ELi is supplied with the i-th light emission control signal EM[i] at the turn-on level, and the fourth transistor TR4 may be set to the turn-on state. During the third period T3, the first scan signal GW[i] at the turn-off level is applied to the i-th first gate line GL1i, and the second transistor TR2 may be set to the turn-off state. During the third period T3, the second scan signal GB[i] at the turn-on level is supplied to the i-th second gate line GL2i, and the third transistor TR3 may remain in the turn-on state.

When the third transistor TR3 is turned on in the third period T3, the first transistor TR1 may control the amount of current supplied from the first power line PL1 to the second node N2 in response to the voltage of the first node N1. When the third transistor TR3 is set to the turn-on state, the current supplied to the second node N2 may be directed to the third power line PL3. During the third period T3, the light-emitting element LD is set to a non-light-emitting state, so that the grayscale expressive power of the display device 100 (refer to FIG. 1) may be improved.

In detail, the voltage of the second node N2 may be raised to a voltage higher than a desired voltage through the second period T2, and thus unnecessary current may be supplied to the light-emitting element LD. In an embodiment, the light-emitting element LD may emit light temporarily even when the black grayscale is implemented in the sub-pixel SPij, for example. Therefore, in the embodiment of the disclosure, the current supplied from the first transistor TR1 is supplied to the third power line PL3 during the third period T3, so that the grayscale power of the display device 100 (refer to FIG. 1) may be improved.

In the third period T3, the voltage of the first node N1 may rise to the first power supply voltage VDD. Accordingly, the voltage change amount of the first node N1 may be expressed as Equation 13.

$$VN ( 1 ) = Vdata [ i ] + α Δ Vs \qquad [ Equation 13 ]$$

In Equation 13, “VN(1)” refers to the voltage of the first node N1. “Vdata[i]” denotes the data voltage Vdata[i]. “AVs” may denote a voltage change amount of the third node N3. “a” refers to the ratio at which the voltage change of the third node N3 is reflected in the voltage change of first node N1. Equation 13 is the same as Equation 2 above.

“AVs” may be calculated as shown in Equation 14 below.

$$Δ Vs = VDD - ( Vdata [ i ] + \vert Vth\_TR1 \vert ) \qquad [ Equation 14 ]$$

Equation 14 is the same as Equation 3 above.

“α” may be calculated as shown in Equation 15 below.

$$α = \frac{c 1}{c 1 + c 3} \qquad [ Equation 15 ]$$

In Equation 15, “c1” refers to the storage capacity of the first capacitor C1. “c3” denotes the storage capacity of the third capacitor C3. Equation 15 is the same as Equation 4 above.

The voltage of the second node N2 in the third period T3 may be equal to the third power supply voltage VINT.

As the level of the first scan signal GW[i] transitions from the turn-on level to the turn-off level while proceeding from the second period T2 to the third period T3, and the voltage applied to the j-th data line DLj fluctuates, a ripple voltage may be applied to the second node N2. The second capacitor C2 may mitigate (e.g., minimize) the variation of the voltage of the second node N2 from the third power supply voltage VINT due to the ripple voltage. Accordingly, the voltage of the second node N2 may be maintained at the third power supply voltage VINT.

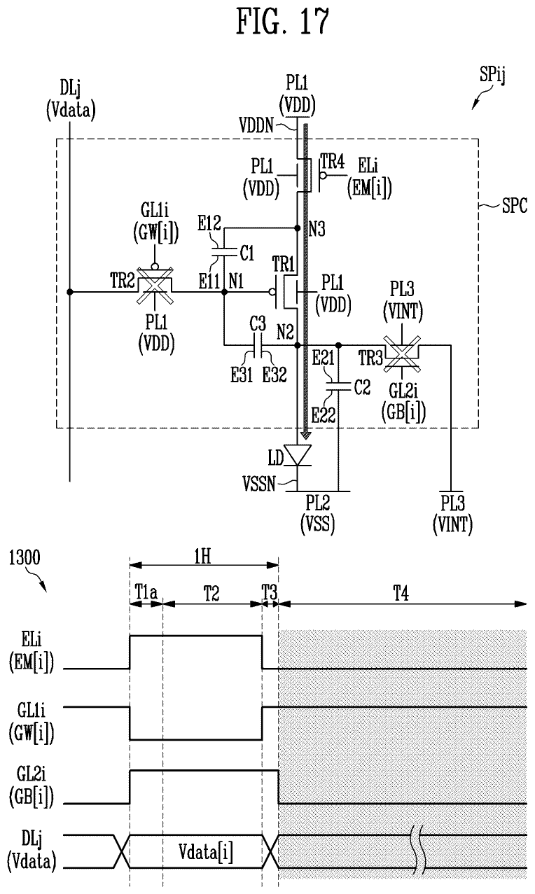

Referring to FIG. 17, during the fourth period T4, the second scan signal GB[i] at the turn-off level is applied to the i-th second gate line GL2i, and the third transistor TR3 may be turned off. During the fourth period T4, the first scan signal GW[i] at the turn-off level is applied to the i-th first gate line GL1i, and the second transistor TR2 may be in the turn-off state. During the fourth period T4, the i-th light emission control signal EM[i] at the turn-on level is applied to the i-th light emission control line ELi, and the fourth transistor TR4 may be in the turn-on state.

FIG. 17 is a diagram illustrating a fourth period T4 of the driving method 1300.

In the fourth period T4, the first transistor TR1 may control the amount of current supplied from the first power supply voltage node VDDN to the second power supply voltage node VSSN via the light-emitting element LD in response to the voltage of the first node N1. During the fourth period T4, the light-emitting element LD may generate light having a luminance corresponding to the amount of driving current supplied from the first transistor TR1.

During the fourth period T4, the voltage of the second node N2 may be changed from the third power supply voltage VINT to a predetermined voltage. The voltage change amount of the second node N2 during the fourth period T4 is as shown in Equation 16 below.

$$Δ {V}_{A} = {V}_{{A}^{′}} - VINT \qquad [ Equation 16 ]$$

In Equation 16, “ΔV_{A}” refers to the amount of voltage change of the second node N2. “V_{A}” refers to the voltage of the second node N2 in the fourth period T4. “VINT” refers to the third power supply voltage VINT, and may correspond to the voltage of the second node N2 in the third period T3. Equation 16 is the same as Equation 5 above.

Due to the coupling phenomenon of the third capacitor C3, the voltage of the first node N1 may fluctuate as shown in Equation 17 below.

$$VN ( 1 ) = Vdata [ i ] + α Δ Vs + β Δ {V}_{A} \qquad [ Equation 17 ]$$

In Equation 17, “VN(1)” refers to the voltage of the first node N1. “Vdata[i]+αΔVs” corresponds to the voltage of the first node N1 in the third period T3. “β” refers to the ratio at which the voltage change of the second node N2 is reflected in the voltage change of first node N1. “ΔV_{A}” is as calculated in Equation 16. Equation 17 is the same as Equation 6 above.

“β” may be calculated as shown in Equation 18 below.

$$β = \frac{c 3}{c 1 + c 3} \qquad [ Equation 18 ]$$

In Equation 18, “c1” refers to the storage capacity of the first capacitor C1. “c3” denotes the storage capacity of the third capacitor C3. Equation 18 is the same as Equation 7 above.

Using Equations 15, 16, and 18 to rewrite Equation 17, the voltage of the first node N1 may be expressed as Equation 19 below.

$$VN ( 1 ) = Vdata [ i ] + \frac{c 1}{c 1 + c 3} \{ VDD - ( Vdata [ i ] + \vert Vth\_TR 1 \vert ) \} + \frac{c 1}{c 1 + c 3} ( {V}_{{A}^{′}} - VINT ) \qquad [ Equation 19 ]$$

Equation 19 is the same as Equation 8 above.

The voltage difference between the source electrode and the gate electrode of the first transistor TR1 in the fourth period T4 may be expressed as Equation 20 below.

$$Vsg = VDD - \text{} [ Vdata [ i ] + \frac{c 1}{c 1 + c 3} ( VDD - ( Vdata [ i ] + \vert Vth\_TR1 \vert ) \} + \frac{c 3}{c 1 + c 3} ( {V}_{{A}^{′}} - VINT ) ] \qquad [ Equation 20 ]$$

In Equation 20, “Vsg” may correspond to a voltage difference between the source electrode and the gate electrode of the first transistor TR1. The voltage of the source electrode may be equal to the first power supply voltage VDD. The voltage of the gate electrode may be equal to “VN(1)”, which is the voltage of the first node in Equation 19. Equation 20 is the same as Equation 9 above.

The magnitude of the driving current flowing through the light-emitting element LD in the first transistor TR1 in the fourth period T4 is as shown in Equation 21 below.

$${I}_{LD} = \frac{1}{2} μ Cox \frac{W}{L} {( Vsg - \vert {Vth\_TR1}^{′} \vert )}^{2} \qquad [ Equation 21 ]$$

In Equation 21, “I_{LD}” refers to the magnitude of the driving current flowing through a light-emitting element LD. “μ” refers to the electron mobility of the first transistor TR1. “Cox” refers to the oxide capacitance of the first transistor TR1. “W” refers to the channel width of the first transistor TR1. “L” refers to the channel length of the first transistor TR1. “Vsg” is the same as calculated in Equation 20. “|Vth_TR1′]” may refer to the threshold voltage of the first transistor TR1 in the fourth period T4 as the second threshold voltage. Equation 21 is the same as Equation 10 above.

When Equation 21 is solved, it is as shown in Equation 22 below.

$$[ Equation 22 ]$$

$$\text{?} \frac{1}{2} μ Cox \frac{W}{L} \{ \frac{c 3}{c 1 + c 3} ( VDD - Vdata [ i ] ) + \frac{c 1}{c 1 + c 3} \vert Vth\_TR 1 \vert - \frac{c 3}{c 1 + c 3} ( {V}_{{A}^{′}} - VINT ) - \vert Vth\_TR 1 \vert \} \text{?}$$

$$\text{?} \text{indicates text missing or illegible when filed}$$

Equation 22 is the same as Equation 11 above.

Referring to Equation 22, the data voltage Vdata[i] may be reflected in the driving current (e.g., I_{LD} in Equation 22) as a value multiplied by the ratio of the capacities of the first and third capacitors C1 and C3 (e.g., c3/(c1+c3) in Equation 22). When the data voltage Vdata[i] is reflected in the driving current corresponding to the ratio of the capacitors, the range of the data voltage may be relatively wide.

Referring further to FIG. 1, when converting the input image data IMG into image data DATA, the controller 150 may generate the image data DATA based on the capacitance of the first capacitor C1 (e.g., c1 in Equation 22) and the capacitance of the third capacitor C3 (e.g., c3 in Equation 22). The data driver 130 may generate a data voltage Vdata corresponding to the input image data DATA.

In an embodiment, the range of the data voltage is set to be relatively small when the data voltage Vdata[i] is directly reflected in the driving current (or the coefficient multiplied by the data voltage Vdata[i] equal to or greater than 1). In this case, it is relatively difficult to implement various gray levels using a relatively small range of data voltages, and thus to stably implement a preset gray level. When the range in which the data voltage may be set is widened by multiplying the data voltage by the value of a smaller coefficient as in the application, a preset grayscale may be stably implemented.

In addition, the absolute value of the threshold voltage of the first transistor TR1 (e.g., |Vth_TR1| in Equation 22) may be reflected in the driving current corresponding to the ratio of the capacities of the first and third capacitors C1 and C3 (e.g., c1/(c1+c3) in Equation 22). In this case, the influence of the threshold voltage of the first transistor TR1 may be mitigated.

The difference between the voltage of the second node N2 and the third power supply voltage VINT (e.g., V_{A}′−VINT in Equation 22) may be reflected in the driving current corresponding to the ratio of the capacities of the first and third capacitors C1 and C3 (e.g., c3/(c1+c3) in Equation 11. In this case, the influence of the voltage fluctuation of the second node N2 is mitigated, so that visibility may be improved.

FIG. 18 is a plan view showing an embodiment of the display panel DP of FIG. 1.

Referring to FIG. 18, an embodiment of the display panel 110 of FIG. 1 may include a display area DA and a non-display area NDA. The display panel DP displays an image through the display area DA. The non-display area NDA is disposed around the display area DA.

The display panel DP may include a substrate SUB, a sub-pixel SP, and a pad PD.

When the display panel DP is used as a display screen of a head-mounted display (“HMD”) device, a virtual reality (“VR”) device, a mixed reality (“MR”) device, an augmented reality (“AR”) device, or the like, the display panel DP may be disposed substantially close to the user's eyes. In this case, sub-pixels SP with a relatively high degree of integration are desired. In an embodiment in which the substrate SUB is provided as a silicon substrate, the degree of integration of the sub-pixels SP may be increased. The sub-pixels SP and/or the remaining components of the display panel DP may be formed on the substrate SUB which is a silicon substrate in the above embodiment. A display device 100 (refer to FIG. 1) including a display panel DP formed on a substrate SUB that is a silicon substrate may be also referred to as (an organic light-emitting diode (“OLED”) on Silicon (“OLEDOS”) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not so limited. In an embodiment, the sub-pixels SP may be arranged in a zigzag shape along the first direction DR1 and the second direction DR2, for example. In an embodiment, the sub-pixels SP may be arranged in the form of a PENTILE™, for example. The first direction DR1 may be a row direction and the second direction DR2 may be a column direction.

Two or more sub-pixels of the plurality of sub-pixels SP may constitute one pixel PXL.

In the non-display area NDA on the substrate SUB, a component for controlling the sub-pixels SP may be disposed. In an embodiment, wirings connected to the sub-pixels SP such as the first to m-th gate lines GL1 to GLm and the first to n-th data lines DL1 to DLn of FIG. 1 may be disposed in the non-display area NDA, for example.

At least one of the gate driving circuit 120, the data driver 130, the voltage generator 140, the controller 150, and the temperature sensor 160 of FIG. 1 may be integrated in the non-display area NDA of the display panel DP. In an embodiment, the gate driving circuit 120 of FIG. 1 may be disposed (e.g., mounted) to the display panel DP and disposed in the non-display area NDA. In other embodiments, the gate driving circuit 120 may be implemented as an integrated circuit separate from the display panel DP. In an embodiment, the temperature sensor 160 may be disposed in the non-display area NDA to sense the temperature of the display panel DP or around the display panel DP.

Pads PD may be disposed in the non-display area NDA. The pads PD may be electrically connected to the sub-pixels SP through wirings. In an embodiment, pads PD may be connected to sub-pixels SP via first through n-th data lines DL1 through DLn, for example.

The pads PD may interface the display panel DP to other components of the display device 100 (refer to FIG. 1). In an embodiment, voltages and signals desired for operation of components included in the display panel DP may be provided from the driver integrated circuit DIC of FIG. 1 through the pads PD. In an embodiment, the first through n-th data lines DL1 through DLn may be connected to a driver integrated circuit DIC via pads PD, for example. In an embodiment, the first and second power supply voltages VDD and VSS may be received from a driver integrated circuit DIC via pads PD, for example. In an embodiment, when the gate driving circuit 120 is disposed (e.g., mounted) on the display panel DP, the gate control signal GCS may be transmitted from the driver integrated circuit DIC to the gate driving circuit 120 through the pad PD, for example.

In an embodiment, a circuit board may be electrically connected to the pads PD using a conductive adhesive such as an anisotropic conductive film. In this case, the circuit board may be a flexible circuit board (“FPCB”) or a flexible film having a flexible material. A driver integrated circuit DIC may be disposed (e.g., mounted) to a circuit board and electrically connected to pads PD.

In an embodiment, the display area DA may have various shapes. The display area DA may have the shape of a closed loop comprising straight and/or curved sides. In an embodiment, the display area DA may have shapes such as a polygon, a circle, a semicircle, an ellipse, etc., for example.

In an embodiment, the display panel DP may have a flat display surface. In other embodiments, the display panel DP may have an at least partially rounded display surface. In an embodiment, the display panel DP may be bendable, foldable, rollable, or stretchable. In such cases, the display panel DP and/or the substrate SUB may comprise materials having a flexible nature.

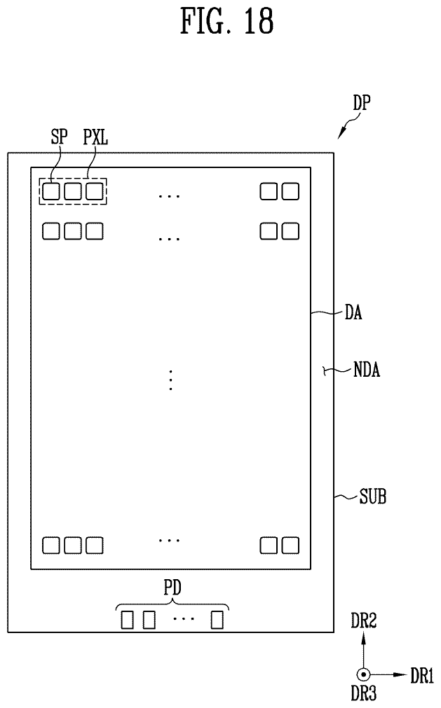

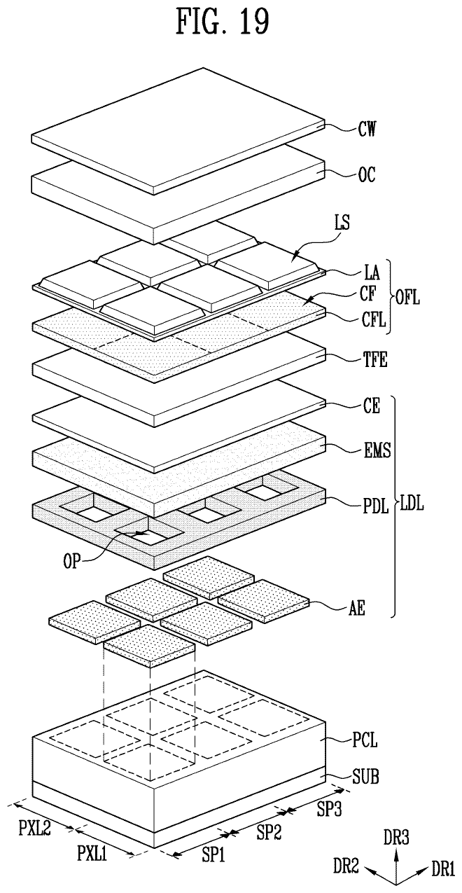

FIG. 19 is an exploded perspective view showing a part of the display panel DP of FIG. 18.

In FIG. 19, for clarity and concise description, a portion of the display panel DP corresponding to two pixels PXL1 and PXL2 among the pixels PXL in FIG. 18 is schematically illustrated. A portion of the display panel DP corresponding to the remaining pixels may be similarly configured.

Referring to FIGS. 18 and 19, each of the first and second pixels PXL1, PXL2 may include first to third sub-pixels SP1, SP2 and SP3. However, the disclosure is not limited thereto. In an embodiment, each of the first and second pixels PXL1, PXL2 may include four sub-pixels, or may include two sub-pixels, for example.

In FIG. 19, the first to third sub-pixels SP1, SP2 and SP3 are shown as having square shapes and having the same sizes as each other when viewed in the third direction DR3 intersecting the first and second directions DR1, DR2. However, embodiments are not so limited. The first to third sub-pixels SP1, SP2 and SP3 may be modified to have various shapes.

The display panel DP may include a substrate SUB, a pixel circuit layer PCL, a light-emitting element layer LDL, a sealing layer TFE, an optical functional layer OFL, an overcoat layer OC, and a cover window CW.

In an embodiment, the substrate SUB may include a silicon wafer substrate formed using a semiconductor process. The substrate SUB may comprise a semiconductor material suitable for forming circuit elements. In an embodiment, the semiconductor material may comprise silicon, germanium, and/or silicon-germanium, for example. A substrate SUB may be provided from a bulk wafer, an epitaxial layer, a Silicon On Insulator (SOI) layer, or a Semiconductor On Insulator (“SeOI”) layer, or the like. In other embodiments, the substrate SUB may comprise a glass substrate. In still other embodiments, the substrate SUB may include a polyimide (“PI”) substrate.

A pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least some of the circuit elements, wirings, or the like. The conductive patterns may include copper, but the disclosure is not limited thereto.

The circuit elements may comprise a sub-pixel circuit (SPC, see FIG. 2) of each of the first to third sub-pixels SP1, SP2 and SP3. A sub-pixel circuit SPC may include transistors and one or more capacitors. Each transistor may include a semiconductor portion including a source region, a drain region, and a channel region, and a gate electrode superimposed on the semiconductor portion. In an embodiment, when the substrate SUB is provided as a silicon substrate, a semiconductor portion is included in the substrate SUB, and a gate electrode may be included in the pixel circuit layer PCL as a conductive pattern of the pixel circuit layer PCL. In an embodiment, when the substrate SUB is provided as a glass substrate or a PI substrate, the semiconductor portion and the gate electrode may be included in the pixel circuit layer PCL. Each capacitor may include electrodes spaced apart from one another. In an embodiment, each capacitor may include electrodes spaced apart from each other in a plan view defined by the first and second directions DR1, DR2, for example. In an embodiment, each capacitor may include electrodes spaced apart from each other in the third direction DR3 with an insulating layer therebetween, for example.

The wirings of the pixel circuit layer PCL may include signal lines connected to each of the first to third sub-pixels SP1, SP2 and SP3, e.g., a gate line, a light emission control line, a data line, or the like. The wirings may further include a wiring connected to the first power supply voltage node VDDN of FIG. 2. In addition, the wirings may further include a wiring connected to the second power supply voltage node VSSN of FIG. 2.

The light-emitting element layer LDL may include anode electrodes AE, pixel defining layer PDL, light-emitting structure EMS, and cathode electrode CE.

The anode electrodes AE may be disposed on the pixel circuit layer PCL. The anode electrodes AE may contact circuit elements of the pixel circuit layer PCL. The anode electrodes AE may comprise an opaque conductive material capable of reflecting light, but the disclosure is not limited thereto.

A pixel defining layer PDL is disposed on the anode electrodes AE. The pixel defining layer PDL may define an opening OP exposing a portion of each of the anode electrodes AE. Light-emitting regions respectively corresponding to the first to third sub-pixels SP1 to SP3 may be defined according to the opening OP of the pixel defining layer PDL. In an alternative embodiment, it may be understood that light-emitting regions corresponding to the first to third sub-pixels SP1 to SP3, respectively, are defined according to the anode electrodes AE. In the region next (adjacent) to the boundary of mutually neighboring sub-pixels, the pixel defining layer PDL may comprise a separator which causes a discontinuity to be formed in the light-emitting structure EMS. In this case, it may be understood that light-emitting regions respectively corresponding to the first to third sub-pixels SP1 to SP3 are defined according to the separators of the pixel defining layer PDL.

In an embodiment, the pixel defining layer PDL may comprise an inorganic material. In this case, the pixel defining layer PDL may comprise a plurality of stacked inorganic layers. In an embodiment, the pixel defining layer PDL may include silicon oxide (SiOₓ) (x is a positive number) and silicon nitride (SiNₓ), for example. In other embodiments, the pixel defining layer PDL may comprise an organic material. However, the material of the pixel defining layer PDL is not limited thereto.

The luminescent structure EMS may be disposed on the anode electrodes AE exposed by the opening OP of the pixel defining layer PDL. The light-emitting structure EMS may include a light-emitting layer which generates light, an electron transport layer which transports electrons, a hole transport layer which transmits holes, or the like.

In an embodiment, the light-emitting structure EMS fills the opening OP of the pixel defining layer PDL, but may be disposed entirely on top of the pixel defining layers PDL. In other words, the light-emitting structure (also referred to as a luminous structure) EMS may extend over the first to third sub-pixels SP1 to SP3. In this case, at least some of the layers in the luminescent structure EMS may break or bend at the boundaries between the first to third sub-pixels SP1 to SP3. However, embodiments are not so limited. In an embodiment, the portions of the light-emitting structure EMS corresponding to the first to third sub-pixels SP1 to SP3 are separated from each other, and each of them may be disposed in the opening OP of the pixel defining layer PDL, for example.

The cathode electrode CE may be disposed on the light-emitting structure EMS. The cathode electrode CE may extend over the first to third sub-pixels SP1 to SP3. As such, the cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may include or consist of a metallic material or of a transparent conductive material so as to have a relatively small thickness. In an embodiment, the cathode electrode CE may include at least one of a variety of transparent conductive materials, including indium tin oxide (“ITO”), indium zinc oxide (“IZO”), indium tin zinc oxide (“ITZO”), aluminum zinc oxide (“AZO”), gallium zinc oxide (“GZO”), tin zinc oxide (“TZO”), or gallium tin oxide (“GTO”). In other embodiments, the cathode electrode CE may comprise at least one of silver (Ag), magnesium (Mg), and combinations thereof. However, the material of the cathode electrode CE is not limited thereto.

Any one of the anode electrodes AE, the part of the light-emitting structure EMS which overlaps it, and the part of the cathode electrode CE which overlaps it may be understood as constituting one light-emitting element LD (refer to FIG. 2). In other words, the light-emitting elements of the first to third sub-pixels SP1 to SP3 may each comprise one anode electrode, a part of the light-emitting structure EMS overlapping therewith, and a part of the cathode electrode CE overlapping therewith. In each of the first to third sub-pixels SP1 to SP3, holes injected from the anode electrode AE and electrons injected from the cathode electrode CE are transported into the light-emitting layer of the light-emitting structure EMS to form excitons, and light may be generated when the excitons transition from the excited state to the ground state. The luminance of light may be determined according to the amount of current flowing through the light-emitting layer. Depending on the configuration of the light-emitting layer, the wavelength range of the generated light may be determined.

A sealing layer (also referred to as an encapsulation layer) TFE is disposed on the cathode electrode CE. The encapsulation layer TFE may cover the light-emitting element layer LDL and/or the pixel circuit layer PCL. The encapsulation layer TFE may prevent oxygen or moisture or the like from penetrating into the light-emitting element layer LDL. In an embodiment, the encapsulation layer TFE may comprise a structure in which one or more inorganic films and one or more organic films are alternately stacked. In an embodiment, the inorganic film may include silicon nitride, silicon oxide, or silicon oxynitride (SiOₓN_{y}) (x, y are positive numbers), or the like, for example. In an embodiment, the organic film may include an organic insulating material such as an acrylic resin, an epoxy resin, a phenol resin, a polyamide resin, a polyimide resin, an unsaturated polyester resin, a polyphenylene ether resin, a polymethylene sulfide resin, or benzocyclobutene (“BCB”), for example. However, the materials of the organic film and the inorganic film of the encapsulation layer TFE are not limited thereto.

The encapsulation layer TFE may further include a thin film including aluminum oxide (AlOₓ) in order to improve the encapsulation efficiency of the encapsulation layer TFE. The thin film comprising aluminum oxide may be disposed on the upper surface of the encapsulation layer TFE facing the optical functional layer OFL and/or on the lower surface of the encapsulation layers TFE facing the light-emitting element layer LDL.

A thin film including or consisting of aluminum oxide may be formed by atomic layer deposition (“ALD”). However, embodiments are not so limited. The encapsulation layer TFE may further comprise a thin film including or consisting of at least one of a variety of materials suitable for improving encapsulation efficiency.

The optical functional layer OFL is disposed on the encapsulation layer TFE. The optical functional layer OFL may comprise a color filter layer CFL and a lens array LA.

The color filter layer CFL is disposed between the encapsulation layer TFE and the lens array LA. The color filter layer CFL filters the light emitted from the light-emitting structure EMS to selectively output light of a wavelength range or color corresponding to each sub-pixel. The color filter layer CFL comprises color filters CF respectively corresponding to the first to third sub-pixels SP1 to SP3, each of which is capable of passing light in a wavelength range corresponding to that sub-pixel. In an embodiment, the color filter corresponding to the first sub-pixel SP1 may pass red color light, the color filter corresponds to the second sub-pixel SP2 may pass green color light, and the color filter corresponding the third sub-pixel SP3 may pass blue color light, for example. Depending on the light emitted from the luminescent structure EMS of each sub-pixel, at least part of the color filters CF may be omitted.

The lens array LA is disposed on the color filter layer CFL. The lens array LA may include lenses LS respectively corresponding to the first to third sub-pixels SP1 to SP3. Each of the lenses LS may output light emitted from the light-emitting structure EMS in the intended path, thereby improving the light exit efficiency. The lens array LA may have a relatively high refractive index. In an embodiment, the lens array LA may have a higher refractive index than the overcoat layer OC, for example. In an embodiment, the lenses LS may comprise an organic material. In an embodiment, the lenses LS may comprise an acrylic material. However, the material of the lenses LS is not limited thereto.

In an embodiment, relative to the opening OP of the pixel defining layer PDL, at least some of the color filters CF of the color filter layer CFL and at least some of lenses LS of the lens array LA may be shifted in a direction parallel to the plane defined by the first and second directions DR1, DR2. Specifically, in the central region of the display area DA, the center of the color filter and the center of the lens may be aligned or overlapped with the center of the opening OP of the corresponding pixel defining layer PDL when viewed in the third direction DR3. In an embodiment, in the central region of the display area DA, the opening OP of the pixel defining layer PDL may completely overlap the corresponding color filter of the color filter layer CFL and the corresponding lens of the lens array LA, for example. In the area next (adjacent) to the non-display area NDA in the display area DA, the center of the color filter and the center of the lens may be shifted in a planar direction from the center of the opening OP of the corresponding pixel defining layer PDL when viewed in the third direction DR3. In an embodiment, in a region next (adjacent) to the non-display area NDA in the display area DA, the opening OP of the pixel defining layer PDL may partially overlap the corresponding color filter of the color filter layer CFL and the corresponding lens of the lens array LA, for example. Accordingly, in the center of the display area DA, the light emitted from the light-emitting structure EMS may be efficiently output in the direction normal to the display surface. Outside the display area DA, light emitted from the light-emitting structure EMS may be efficiently output in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light-emitting structure EMS, and/or the pixel circuit layer PCL. The overcoat layer OC may comprise a variety of materials suitable for protecting the underlying layers thereof from foreign matter such as dust, moisture, etc. In an embodiment, the overcoat layer OC may include at least one of an inorganic insulating film and an organic insulating film, for example. In an embodiment, the overcoat layer OC may include, but is not limited to, epoxy, for example. The overcoat layer OC may have a lower refractive index than the lens array LA.

The cover window CW may be disposed on the overcoat layer OC. The cover window CW protects its lower layers. The cover window CW may have a higher refractive index than the overcoat layer OC. The cover window CW may include glass, but the disclosure is not limited thereto. In an embodiment, the cover window CW may be an encapsulation glass which protects components disposed below it, for example. In other embodiments, the cover window CW may be omitted.

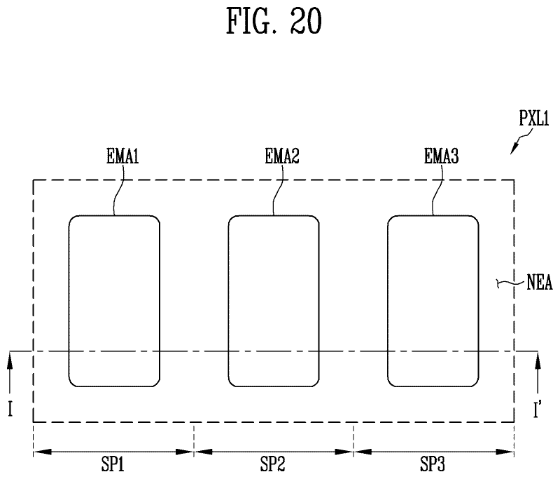

FIG. 20 is a plan view showing an embodiment of any one of the pixels of FIG. 19.

In FIG. 20, a first pixel PXL1 of the first and second pixels PXL1 and PXL2 of FIG. 19 is schematically shown for clear and concise description. The remaining pixels may be configured similarly to the first pixel PXL1.

Referring to FIGS. 19 and 20, the first pixel PXL1 may include first to third sub-pixels SP1 to SP3 arranged in the first direction DR1.

The first sub-pixel SP1 may include a first light-emitting area EMA1 and a non-light-emitting area NEA around the first light-emitting area EMA1. The second sub-pixel SP2 may include a second light-emitting area EMA2 and a non-light-emitting area NEA around the second light-emitting area EMA2. The third sub-pixel SP3 may include a third light-emitting area EMA3 and a non-light-emitting area NEA around the third light-emitting area EMA3.

The first light-emitting area EMA1 may be a region where light is emitted from a portion of the light-emitting structure EMS (refer to FIG. 19) corresponding to the first sub-pixel SP1. The second light-emitting area EMA2 may be an area from which light is emitted from a portion of the light-emitting structure EMS corresponding to the second sub-pixel SP2. The third light-emitting area EMA3 may be an area where light is emitted from a portion of the light-emitting structure EMS corresponding to the third sub-pixel SP3.

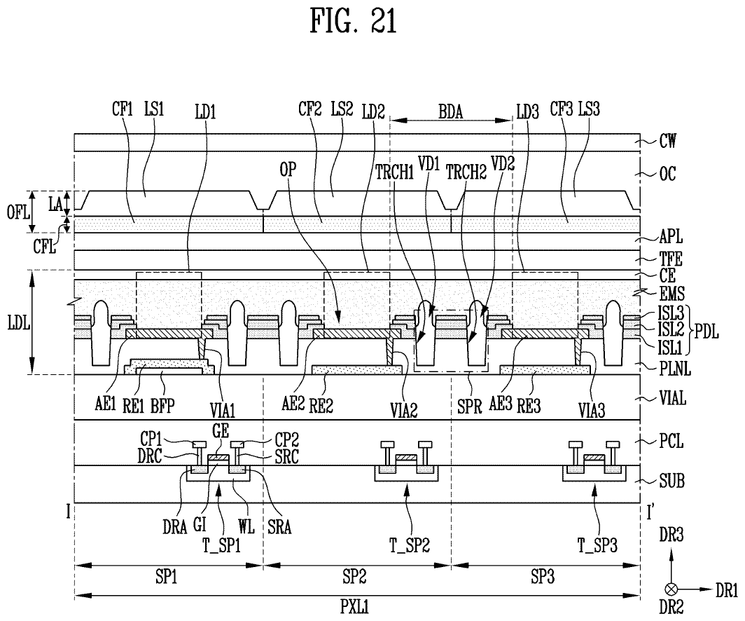

FIG. 21 is a cross-sectional view taken along line I-I′ of an embodiment of FIG. 20 according to the disclosure.

Referring to FIG. 21, a substrate SUB and a pixel circuit layer PCL disposed on the substrate SUB are provided.

The substrate SUB may include a silicon wafer substrate formed using a semiconductor process. In an embodiment, the substrate SUB may comprise silicon, germanium, and/or silicon-germanium, for example.

A pixel circuit layer PCL is disposed on the substrate SUB. The substrate SUB and the pixel circuit layer PCL may include circuit elements of each of the first to third sub-pixels SP1 to SP3. In an embodiment, the substrate SUB and the pixel circuit layer PCL may include the transistor T_SP1 of the first sub-pixel SP1, the transistor T_SP2 of the second sub-pixel SP2, and the transistor T_SP3 of the third sub-pixel SP3, for example. The transistor T_SP1 of the first sub-pixel SP1 may be any one of transistors included in a sub-pixel circuit SPC (refer to FIG. 2) of the first sub-pixel SP1, the transistor T_SP2 of the second sub-pixel SP2 may be any one the transistors included in the sub-pixel circuit SPC of the second sub-pixel SP2, and the transistor T_SP3 of the third sub-pixel SP3 may be any one a transistor included in the sub-pixel circuit SPC of the third sub-pixel SP3. In FIG. 21, for the sake of clarity and brevity, one of the transistors of each sub-pixel is shown, and the remaining circuit elements are omitted.

The transistor T_SP1 of the first sub-pixel SP1 may include a source region SRA, a drain region DRA, and a gate electrode GE.

The source region SRA and the drain region DRA may be disposed within the substrate SUB. A well WL formed through the ion implantation process is disposed in the substrate SUB, and a source region SRA and a drain region DRA may be spaced apart from each other in the well WL. The region between the source region SRA and the drain region DRA in the well WL may be defined as a channel region. The gate electrode GE overlaps the channel region between the source region SRA and the drain region DRA, and may be disposed in the pixel circuit layer PCL. The gate electrode GE may be spaced apart from the well WL or channel region by an insulating material, such as a gate insulating layer GI. The gate electrode GE may comprise a conductive material.

The plurality of layers included in the pixel circuit layer PCL include insulating layers and conductive patterns disposed between the insulating layers, and such conductive patterns may include first and second conductive patterns CP1 and CP2. The first conductive pattern CP1 may be electrically connected to the drain region DRA via a drain connection DRC through one or more insulating 0 layers. The second conductive pattern CP2 may be electrically connected to the source region SRA via a source connection SRC through one or more insulating layers.

In an embodiment, the first and second conductive patterns CP1 and CP2 may comprise the electrode layer SD of FIGS. 6 and 7 described above.

As the gate electrode GE and the first and second conductive patterns CP1 and CP2 are connected to other circuit elements and/or wirings, the transistor T_SP1 of the first sub-pixel SP1 may be provided as any one of the transistors of the first sub-pixel SP1.

The transistor T_SP2 of the second sub-pixel SP2 and the transistor T_SP3 of the third sub-pixel SP3 may be configured similarly to the transistor T_SP1 of the first sub-pixel SP1.

As such, the substrate SUB and the pixel circuit layer PCL may include circuit elements of each of the first to third sub-pixels SP1 to SP3.

A via layer VIAL is disposed on the pixel circuit layer PCL. The via layer VIAL covers the pixel circuit layer PCL, but may have an overall flat surface. The via layer VIAL planarizes the steps on the pixel circuit layer PCL. The via layer VIAL may include, but is not limited to, at least one of silicon oxide (SiOₓ), silicon nitride (SiNₓ), silicon carbon nitride (SiCN).

A light-emitting element layer LDL is disposed on the via layer VIAL. The light-emitting element layer LDL may include first to third reflective electrodes RE1 to RE3, a planarization layer PLNL, first to third anode electrodes AE1 to AE3, a pixel defining layer PDL, a light-emitting structure EMS, and a cathode electrode CE.

On the via layer VIAL, first to third reflective electrodes RE1 to RE3 are respectively arranged in the first to third sub-pixels SP1 to SP3. Each of the first to third reflective electrodes RE1 to RE3 may contact a circuit element disposed in the pixel circuit layer PCL through a via penetrating the via layer VIAL.

The first to third reflective electrodes RE1 to RE3 may function as a full mirror that reflects light emitted from the light-emitting structure EMS toward the display surface (or the cover window CW). The first to third reflective electrodes RE1 to RE3 may comprise metallic materials suitable for reflecting light. The first to third reflective electrodes RE1 to RE3 may include, but are not limited to, at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom.

In an embodiment, a connecting electrode may be disposed below each of the first to third reflective electrodes RE1 to RE3. The connection electrode may improve the electrical connection characteristics between the reflection electrode and the circuit element of the pixel circuit layer PCL. The connecting electrode may have a multilayer structure. The multilayer structure may include, but is not limited to, titanium (Ti), titanium nitride (TIN), tantalum nitride (TaN), or the like. In an embodiment, a corresponding reflective electrode may be disposed between the multiple layers of the connecting electrode.

A buffer pattern BFP may be disposed under at least one of the first to third reflective electrodes RE1 to RE3. The buffer pattern BFP may include an inorganic material such as, but not limited to, silicon carbon nitride. By arranging the buffer pattern BFP, the height of the reflective electrode in the third direction DR3 may be adjusted. In an embodiment, the buffer pattern BFP may be disposed between the first reflective electrode RE1 and the via layer VIAL to adjust the height of the first reflective electrode RE1, for example.

The first to third reflective electrodes RE1 to RE3 may function as full mirrors and the cathode electrode CE may function as a half mirror. In an embodiment, each of the first to third reflective electrodes RE1 to RE3 and the cathode electrode CE may provide a resonant structure in that sub-pixel, for example. The light emitted from the light-emitting layer of the light-emitting structure EMS may be amplified by reciprocating between the corresponding reflective electrode and the cathode electrode CE, and the amplified light may be output through the cathode electrode CE. As such, the distance between each reflective electrode and the cathode electrode CE may be understood as the resonance distance for light emitted from the light-emitting layer of the corresponding light-emitting structure EMS.

The first sub-pixel SP1 may have a shorter resonance distance than other sub-pixels due to the buffer pattern BFP. Such an adjusted resonance distance may allow light in a particular wavelength range (e.g., red color) to be effectively and efficiently amplified. Accordingly, the first sub-pixel SP1 may effectively and efficiently output light in the corresponding wavelength range.

Although the buffer pattern BFP is shown in FIG. 21 as being provided in the first sub-pixel SP1 and not in the second and third sub-pixels SP2, SP3, the disclosure is not limited thereto. A buffer pattern BFP may also be provided in at least one of the second and third sub-pixels SP2 and SP3 to adjust the resonance distance of at least the one of the second or third sub-pixel SP2 or SP3. In an embodiment, the first to third sub-pixels SP1 to SP3 correspond to red, green, and blue, respectively, the distance between the first reflective electrode RE1 and the cathode electrode CE may be shorter than the distance between the second reflective electrode RE2 and the cathode electrode CE, and the distance between the two second reflective electrodes RE2 and the cathode electrode CE may be smaller than the distance between a third reflective electrode RE3 and a cathode electrode CE, for example.

To planarize the steps between the first to third reflective electrodes RE1 to RE3, a planarization layer PLNL may be disposed on the via layer VIAL and the first to third reflective electrodes RE1 to RE3. The planarization layer PLNL generally covers the first to third reflective electrodes RE1 to RE3 and the via layer VIAL, but may have a flat surface. In an embodiment, the planarization layer PLNL may be omitted.

On the planarization layer PLNL, first to third anode electrodes AE1 to AE3 are arranged which respectively overlap the first to third reflective electrodes RE1 to RE3. The first to third anode electrodes AE1 to AE3 may have shapes similar to the first to third light-emitting areas EMA1 to EMA3 of FIG. 20 when viewed in the third direction DR3. The first to third anode electrodes AE1 to AE3 are connected to the first to third reflective electrodes RE1 to RE3, respectively. The first anode electrode AE1 may be connected to the first reflective electrode RE1 via a first via VIA1 through the planarization layer PLNL. The second anode electrode AE2 may be connected to the second reflective electrode RE2 via a second via VIA2 through the planarization layer PLNL. The third anode electrode AE3 may be connected to the third reflective electrode RE3 via a third via VIA3 through the planarization layer PLNL.

In an embodiment, the first to third anode electrodes AE1 to AE3 may comprise at least one of transparent conductive materials such as indium tin oxide (“ITO”), indium zinc oxide (“IZO”), zinc oxide (ZnO), indium gallium zinc oxide (“IGZO”), indium tin zinc oxide (“ITZO”). However, the material of the first to third anode electrodes AE1 to AE3 is not limited thereto. In an embodiment, the first to third anode electrodes AE1 to AE3 may comprise titanium nitride, for example.

A pixel defining layer PDL is disposed on the planarization layer PLNL and portions of the first to third anode electrodes AE1 to AE3. The pixel defining layer PDL defines an opening OP which exposes a part of each of the first to third anode electrodes AE1 to AE3. A region overlapping the pixel defining layer PDL may be understood as a boundary area BDA between sub-pixels next (adjacent) to each other.

In an embodiment, the pixel defining layer PDL may include a plurality of inorganic insulating layers. Each of the plurality of inorganic insulating layers may include at least one of silicon oxide (SiOₓ) and silicon nitride (SiNₓ). In an embodiment, the pixel defining layer PDL may include a first inorganic insulating layer ISL1, a second inorganic insulating layer ISL2, and a third inorganic insulating layer ISL3, which are sequentially stacked, for example. The first to third inorganic insulating layers ISL1 to ISL3 may include, but are not limited to, silicon nitride, silicon oxide, and silicon nitride. The first to third inorganic insulating layers ISL1 to ISL3 may have a stepped cross-section in a region next (adjacent) to the opening OP.

The pixel defining layer PDL may comprise a separator SPR in a boundary area BDA between sub-pixels next (adjacent) to each other. In other words, a separator SPR may be provided in each of the boundary regions between the sub-pixels SP of FIG. 18.

The separator SPR may cause a discontinuous portion to form in the luminescent structure EMS in the boundary area BDA. In an embodiment, by means of the separator SPR, the luminescent structure EMS may be broken or bent in the boundary area BDA, for example. Accordingly, the first to third light-emitting areas EMA1 to EMA3 of FIG. 20 respectively corresponding to the first to third sub-pixels SP1 to SP3 may be defined according to the separator SPR of the pixel defining layer PDL.

A separator SPR may be provided in or on the pixel defining layer PDL. The pixel defining layer PDL may comprise one or more trenches TRCH1 and TRCH2 as a separator SPR in the boundary area BDA. In an embodiment, one or more trenches TRCH1 and TRCH2 may penetrate pixel defining layer PDL and partially penetrate planarization layer PLNL, as shown in FIG. 21. In other embodiments, one or more trenches TRCH1 and TRCH2 may penetrate pixel defining layer PDL and planarization layer PLNL, and partially penetrate via layer VIAL. In other embodiments, the one or more trenches TRCH1 and TRCH2 at least partially penetrate the planarization layer PLNL and/or the via layer VIAL, and a portion of the pixel defining layer PDL may be disposed within the one or more of the trenches TRCH1, TRCH2.

In FIG. 21, it is shown that two trenches TRCH1 and TRCH2 are provided in the boundary area BDA. However, the disclosure is not limited thereto. In an embodiment, the pixel defining layer PDL may include one trench in the boundary area BDA, for example. In an alternative embodiment, the pixel defining layer PDL may include three or more trenches in the boundary area BDA.

Due to the first and second trenches TRCH1, TRCH2, discontinuous portions such as the first void VD1 and the second void VD2 in the boundary area BDA may be defined in the light-emitting structure EMS. Some of the plurality of layers stacked in the light-emitting structure EMS may be broken or bent by the first and second voids VD1 and VD2. In an embodiment, the at least one charge generation layer and the at least one hole injection layer included in the light-emitting structure EMS may break at the first and second voids VD1 and VD2, for example. As such, due to the first and second trenches TRCH1, TRCH2, the portions of the light-emitting structure EMS comprised in the first to third sub-pixels SP1 to SP3 may be at least partially separated.

Depending on the shapes of the first and second trenches TRCH1, TRCH2, the discontinuous portions formed in the light-emitting structure EMS may vary.

In an embodiment, a light-emitting structure EMS may be formed through a process such as vacuum deposition, inkjet printing, etc. In this case, the same materials as the luminescent structure EMS may be disposed on the bottom surfaces of the first and second trenches TRCH1 and TRCH2 next (adjacent) to the via layer VIAL.

The pixel defining layer PDL may comprise an additional separator such that the luminescent structure EMS further comprises a discontinuous portion next (adjacent) to the boundary area BDA. In an embodiment, the uppermost third inorganic insulating layer ISL3 among the first to third inorganic insulating layers ISL1 to ISL3 of the pixel defining layer PDL may have a wider width than the second inorganic insulating layer ISG2 disposed directly below it. In an embodiment, the pixel defining layer PDL may have a “T”-shaped or “I”-shaped cross-section in the boundary area BDA, for example. Depending on the shape of the pixel defining layer PDL, the plurality of layers included in the luminescent structure EMS may be at least partially broken or bent in the boundary area BDA or in a region next (adjacent) to the boundary area BDA.

The luminescent structure EMS may be disposed on the anode electrodes AE exposed by the opening OP of the pixel defining layer PDL. The light-emitting structure EMS fills the opening OP of the pixel defining layer PDL and may be entirely disposed over the first to third sub-pixels SP1 to SP3. As explained above, the luminescent structure EMS may be at least partially broken or bent in the boundary area BDA by the separator SPR. Accordingly, during the operation of the display panel DP, the current flowing out from each of the first to third sub-pixels SP1 to SP3 to a sub-pixel next (adjacent) thereto through the layers included in the light-emitting structure EMS may be reduced. Thus, the first to third light-emitting elements LD1 to LD3 may operate with relatively high reliability.

The cathode electrode CE may be disposed on the light-emitting structure EMS. The cathode electrode CE may be provided in common to the first to third sub-pixels SP1 to SP3. The cathode electrode CE may function as a half mirror that partially transmits and partially reflects light emitted from the light-emitting structure EMS.

The first anode electrode AE1, the part of the light-emitting structure EMS overlapping the first anode electrode AE1, and the part of the cathode electrode CE overlapping the first anode electrodes AE1 may constitute the first light-emitting element LD1. The second anode electrode AE2, the part of the light-emitting structure EMS overlapping the second anode electrode AE2, and the part of the cathode electrode CE overlapping the second anode electrodes AE2 may constitute the second light-emitting element LD2. The third anode electrode AE3, the part of the light-emitting structure EMS overlapping the third anode electrode AE3, and the part of the cathode electrode CE overlapping the third anode electrodes AE3 may constitute the third light-emitting element LD3.

An encapsulation layer TFE is disposed on the cathode electrode CE. The encapsulation layer TFE may prevent oxygen and/or moisture or the like from penetrating into the light-emitting element layer LDL.

An optical functional layer OFL is disposed on the encapsulation layer TFE. In an embodiment, the optical functional layer OFL may be attached to the encapsulation layer TFE via an adhesive layer APL. In an embodiment, the optical functional layer OFL may be produced separately and attached to the encapsulation layer TFE via the adhesive layer APL, for example. The adhesive layer APL may further serve to protect the underlying layers, including the encapsulation layer TFE.

The optical functional layer OFL may comprise a color filter layer CFL and a lens array LA. The color filter layer CFL may include first to third color filters CF1 to CF3 corresponding to the first to third sub-pixels SP1 to SP3, respectively. The first to third color filters CF1 to CF3 may pass light of different wavelength ranges. In an embodiment, the first to third color filters CF1 to CF3 may pass light of red, green, and blue colors, respectively, for example.

In an embodiment, the first to third color filters CF1 to CF3 may partially overlap in the boundary area BDA. In other embodiments, the first to third color filters CF1 to CF3 are spaced apart from each other, and a black matrix may be provided between the first to third colors filters CF1 to CF3.

The lens array LA is disposed on the color filter layer CFL. The lens array LA may include first to third lenses LS1 to LS3 corresponding to the first to third sub-pixels SP1 to SP3, respectively. Each of the first to third lenses LS1 to LS3 outputs light emitted from the first to third light-emitting elements LD1 to LD3 in an intended path, thereby improving light emission efficiency.

An overcoat layer OC may be disposed on the lens array LA. The overcoat layer OC protects its lower layers from foreign materials such as dust, moisture, etc. A cover window CW may be disposed on the overcoat layer OC.

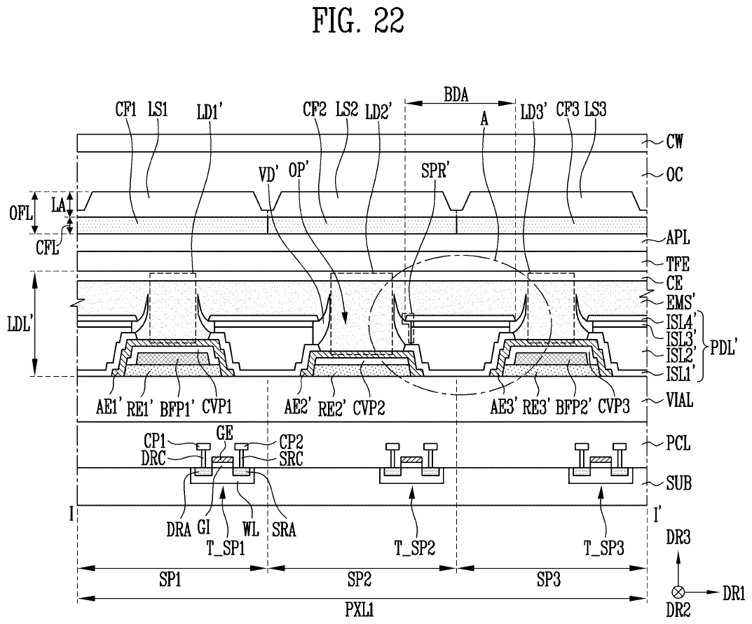

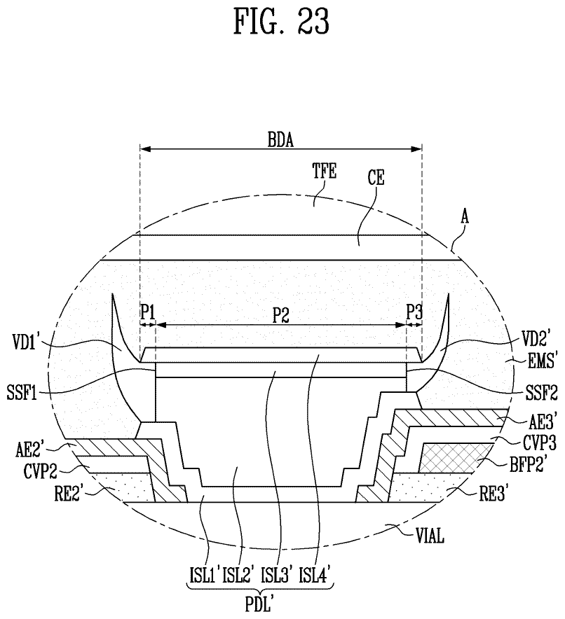

FIG. 22 is a cross-sectional view taken along line I-I′ of an embodiment of FIG. 20 according to the disclosure. FIG. 23 is an enlarged view showing an area A of FIG. 22.

Referring to FIG. 22, a pixel circuit layer PCL and a via layer VIAL are disposed on a substrate SUB. The substrate SUB, the pixel circuit layer PCL, and the via layer VIAL in FIG. 22 are configured similarly to the substrate SUB, pixel circuit layer PCL, and via layer VIAL, respectively, in FIG. 21. Hereinafter, overlapping explanations are omitted.

A light-emitting element layer LDL′ is disposed on the via layer VIAL. The light-emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel defining layer PDL′, a light-emitting structure EMS′, and a cathode electrode CE.

On the via layer VIAL, first to third reflective electrodes RE1′ to RE3′ are respectively arranged in the first to third sub-pixels SP1 to SP3. Each of the first to third reflective electrodes RE1′ to RE3′ may contact a circuit element disposed in the pixel circuit layer PCL through a via penetrating the via layer VIAL.

The first to third reflective electrodes RE1′ to RE3′ reflect light emitted from the luminescent structure EMS' towards the display surface (or the cover window CW). The first to third reflective electrodes RE1′ to RE3′ may comprise metallic materials suitable for reflecting light. The first to third reflective electrodes RE1′ to RE3′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but are not limited to.

In an embodiment, a connecting electrode may be further provided between each of the first to third reflective electrodes RE1′ to RE3′ and the via layer VIAL. The connection electrode may improve the electrical connection characteristics between the reflection electrode and the circuit element of the pixel circuit layer PCL. The connecting electrode may have a multilayer structure. The multilayer structure may include, but is not limited to, titanium (Ti), aluminum (Al), titanium nitride (TIN), tantalum nitride (TaN), or the like. In an embodiment, a corresponding reflective electrode may be disposed between the multiple layers of the connecting electrode.

A buffer pattern may be disposed on at least one of the first to third reflective electrodes RE1′ to RE3′. In an embodiment, the first and second buffer patterns BFP1′ and BFP2′ may be disposed on the first and third reflective electrodes RE1′ and RE3′, respectively. The heights of the first and third anode electrodes AE1′ and AE3′ in the third direction DR3 may be adjusted by means of the first and second buffer patterns BFP1′ and BFP2′. The first and second buffer patterns BFP1′ and BFP2′ may include inorganic materials such as, but not limited to, silicon oxide (SiOₓ) and silicon nitride (SiNₓ).

First to third cover patterns CVP1 to CVP3 may be respectively disposed on the first to third reflective electrodes RE1′ to RE3′. In the first sub-pixel SP1, the first cover pattern CVP1 is disposed on the first reflective electrode RE1′ and the first buffer pattern BFP1′. In the second sub-pixel SP2, a second cover pattern CVP2 is disposed on the second reflective electrode RE2′. In the third sub-pixel SP3, a third cover pattern CVP3 is disposed on the third reflective electrode RE3′ and the second buffer pattern BFP2′. The first to third cover patterns CVP1 to CVP3 may be formed after the formation of the first and second buffer patterns BFP1′ and BFP2′ during the manufacturing process. The first to third cover patterns CVP1 to CVP3 may comprise the same material as that of the first and second buffer patterns BFP1′ and BFP2′. In an embodiment, the first to third cover patterns CVP1 to CVP3 may include an inorganic material such as silicon oxide (SiOₓ) and silicon nitride (SiNₓ), for example, but the disclosure is not limited thereto.

First to third anode electrodes AE1′ to AE3′ are respectively arranged on the first to third cover patterns CVP1 to CVP3. In an embodiment, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. In an embodiment, each anode electrode may be connected to the end (or edge) of that reflective electrode, for example. However, embodiments are not so limited. In order to improve the electrical connection characteristics between the anode electrode and the reflective electrode, the anode electrode may be connected to the reflective electrode in various ways.

In an embodiment, the first to third anode electrodes AE1′ to AE3′ may comprise at least one of transparent conductive materials such as indium tin oxide (“ITO”), indium zinc oxide (“IZO”), zinc oxide (ZnOₓ), indium gallium zinc oxide (“IGZO”), indium tin zinc oxide (“ITZO”). However, the material of the first to third anode electrodes AE1′ to AE3′ is not limited thereto. In an embodiment, the first to third anode electrodes AE1′ to AE3′ may comprise titanium nitride, for example.

The first to third anode electrodes AE1′ to AE3′ may have shapes similar to the first to third light-emitting areas EMA1 to EMA3 of FIG. 20 when viewed in the third direction DR3.

The first to third anode electrodes AE1′ to AE3′ and the cathode electrode CE may partially reflect incident light. The light emitted from the light-emitting layer of the light-emitting structure EMS' is amplified by reciprocating between the corresponding anode electrode and the cathode electrode CE, and may be output through the cathode electrode CE. In an embodiment, each anode electrode and cathode electrode CE may provide a resonant structure in that sub-pixel, for example. In this case, the distance between each anode electrode and the cathode electrode CE may be understood as the resonance distance for the light emitted from the light-emitting layer of the corresponding light-emitting structure EMS′.

The first to third sub-pixels SP1 to SP3 may correspond to red, green, and blue, respectively. In this case, the height of the first and third anode electrodes AE1′ and AE3′ in the third direction DR3 may be higher than the second anode electrode AE2′ by means of the first and second buffer patterns BFP1′ and BFP2′. Accordingly, the first and third sub-pixels SP1 and SP3 may have a shorter resonance distance than the second sub-pixel SP2 due to the first and second buffer patterns BFP1′ and BFP2′. In this way, the resonance distance of each sub-pixel may be adjusted so that light in the wavelength range of the corresponding color is effectively and efficiently amplified.

In FIG. 22, the first and second buffer patterns BFP1′ and BFP2′ are shown disposed below the first and third anode electrodes AE1′ and AE3′, respectively, although the disclosure is not limited thereto. In an embodiment, one of the first and second buffer patterns BFP1′ and BFP2′ may be omitted, for example. In another embodiment, both the first and second buffer patterns BFP1′ and BFP2′ may be omitted. In this case, the resonance distance between each anode electrode and the cathode electrode CE may be equal to one another. In another embodiment, a buffer pattern may be disposed below each of the first to third anode electrodes AE1′ to AE3′. In this case, the buffer patterns disposed at the bottom of each anode electrode may have different thicknesses, and thus the resonance distance between each anode electrode and the cathode electrode CE may be different from each other. In this way, by providing a buffer pattern for adjusting the height of at least one of the first to third anode electrodes AE1′ to AE3′, the resonance distance in each sub-pixel may be optimized.

A pixel defining layer PDL′ is disposed on the via layer VIAL and parts of the first to third anode electrodes AE1′ to AE3′. The pixel defining layer PDL′ defines an opening OP′ exposing a portion of each of the first to third anode electrodes AE1′ to AE3′. A region overlapping the pixel defining layer PDL′ may be understood as a boundary area BDA between sub-pixels next (adjacent) to each other.

The pixel defining layer PDL′ may include a plurality of inorganic insulating layers stacked sequentially. Each of the plurality of inorganic insulating layers may include at least one of silicon oxide (SiOₓ) and silicon nitride (SiNₓ). However, embodiments are not so limited. In an embodiment, the pixel defining layer PDL′ may comprise an organic insulating layer, for example.

In an embodiment, the pixel defining layer PDL′ may comprise first to fourth inorganic insulating layers ISL1′ to ISL4′. The first inorganic insulating layer ISL1′ may cover portions of the first to third anode electrodes AE1′ to AE3′ and the via layer VIAL. A second inorganic insulating layer ISL2′ is disposed on the first inorganic insulating layer ISL1′, a third inorganic insulating layer ISL3′ is disposed on a second inorganic insulating layer ISL2′, and a fourth inorganic insulating layer ISL4′ is disposed on third inorganic insulating layer ISL3′. The first and third inorganic insulating layers ISL1′, ISL3′ may comprise silicon nitride (SiNₓ) and the second and fourth inorganic insulating layer ISL2′, ISL4′ may comprise silicon oxide (SiOₓ), although the disclosure is not limited thereto. In an embodiment, the first inorganic insulating layer ISL1′ may be omitted.

The pixel defining layer PDL′ may comprise a separator SPR′ in the boundary area BDA between sub-pixels next (adjacent) to each other. The separator SPR′ may cause a discontinuous portion, such as a void VD′, to be defined in the light-emitting structure EMS′. Due to the discontinuous portions, at least some of the plurality of layers included in the luminescent structure EMS' may break or bend.

The fourth inorganic insulating layer ISL4′ may have a wider width than the second and third inorganic insulating layers ISL2′ and ISL3′. In this case, the sides of the second to fourth inorganic insulating layers ISL2′ to ISL4′ next (adjacent) to the opening OP′ may be provided as a separator SPR′.

Referring to FIG. 23 together with FIG. 22, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third part P3 protrudes from the second part P2 in the first direction DR1. As such, the width of the fourth inorganic insulating layer ISL4′ may be wider than the second and third inorganic insulating layers ISL2′ and ISL3′. In an embodiment, during the manufacturing process, the second and third inorganic insulating layers ISL2′ and ISL3′ may be undercut so as not to include a portion overlapping the first and third portions P1, P3, for example. In an embodiment, each of the first and third portions P1, P3 of the fourth inorganic insulating layer ISL4′ may have an eaves shape on the second and third inorganic insulating layers ISL2′ and ISL3′, for example.

In the boundary area BDA, the second and third inorganic insulating layers ISL2′ and ISL3′ may have the same width as each other. However, the disclosure is not limited thereto, and the second and third inorganic insulating layers ISL2′ and ISL3′ may have different widths from each other. In an embodiment, the second inorganic insulating layer ISL2′ may have a wider width than the third inorganic insulating layer ILS3′, for example. In another embodiment, the third inorganic insulating layer ISL3′ may have a wider width than the second inorganic insulating layer ISL2′.

In the second sub-pixel SP2, the first part P1 of the fourth inorganic insulating layer ISL4′ and the first side SSF1 of the second and third inorganic insulating layers ISL2′ and ISL3′ may be provided as one separator SPR′. Accordingly, a first void VD1′ may be defined in the light-emitting structure EMS' next (adjacent) to the first portion P1 of the fourth inorganic insulating layer ISL4′. In the third sub-pixel SP3, the third portion P3 of the fourth inorganic insulating layer ISL4′ and the second side SSF2 of the second and third inorganic insulating layers ISL2′ and ISL3′ may be provided as another separator SPR′. Accordingly, a second void VD2′ may be defined in the light-emitting structure EMS' next (adjacent) to the third portion P3 of the fourth inorganic insulating layer ISL4′.

Some of the plurality of layers stacked in the luminescent structure EMS' may be broken or bent by the first and second voids VD1′ and VD2′. In an embodiment, the at least one charge generation layer and the at least one hole injection layer comprised in the luminescent structure EMS' may be interrupted by the first and second voids VD1′ and VD2′, for example. As such, due to the separator SPR′, the portions of the light-emitting structure EMS' comprised in the first to third sub-pixels SP1 to SP3 may be at least partially separated from one another.

The pixel defining layer PDL′ may comprise an additional separator such that the luminescent structure EMS' further comprises a discontinuous portion in the boundary area BDA. In an embodiment, the pixel defining layer PDL′ may include one or more trenches as a separator in the boundary area BDA. The trenches may penetrate one or more of the first to fourth inorganic insulating layers ISL1′ to ISL4′. Due to the trenches, some of the plurality of layers stacked in the light-emitting structure EMS′, for example the at least one charge-generation layer and the at least one hole-injection layer, may break or bend. In an embodiment, the light-emitting structure EMS' may have a structure in which three light-emitting portions each including a light-emitting layer are stacked, and two charge generation layers may be disposed between the three light-emitting portions. In such embodiments, the pixel defining layer PDL′ may include one or more trenches in the boundary area BDA.

Referring back to FIG. 22, the light-emitting structure EMS' may be disposed on the anode electrodes AE exposed by the opening OP′ of the pixel defining layer PDL′. The light-emitting structure EMS' fills the opening OP′ of the pixel defining layer PDL′ and may be disposed entirely over the first to third sub-pixels SP1 to SP3. As explained above, the luminescent structure EMS' may be broken or bent by the separator SPR′ in the boundary area BDA or in a region next (adjacent) to the boundary area BDA. Accordingly, during the operation of the display panel DP, the current flowing out from each of the first to third sub-pixels SP1 to SP3 to a sub-pixel next (adjacent) thereto through the layers included in the light-emitting structure EMS' may be reduced. Thus, the first to third light-emitting elements LD1′ to LD3′ may operate with relatively high reliability.

In an embodiment, the light-emitting structure EMS' may comprise two light-emitting portions stacked sequentially, each of the light-emitting portions comprising a light-emitting layer which generates light according to an applied current. In other embodiments, the light-emitting structure EMS' may comprise three light-emitting portions stacked sequentially, each of the light-emitting portions comprising a light-emitting layer which generates light according to an applied current. In such embodiments, a charge generation layer may be disposed between the light-emitting portions.

In an embodiment, the luminescent structure EMS' may be formed through a process such as vacuum deposition, inkjet printing, etc.

The cathode electrode CE may be disposed on the luminescent structure EMS′. The cathode electrode CE may be provided in common to the first to third sub-pixels SP1 to SP3.

The first anode electrode AE1′, the part of the light-emitting structure EMS' overlapping the first anode electrode AE1′, and the part of the cathode electrode CE overlapping the first anode electrodes AE1′ may constitute the first light-emitting element LD1′. The second anode electrode AE2′, the part of the light-emitting structure EMS' overlapping the second anode electrode AE2′, and the part of the cathode electrode CE overlapping the second anode electrodes AE2′ may constitute the second light-emitting element LD2′. The third anode electrode AE3′, the part of the light-emitting structure EMS' overlapping the third anode electrode AE3′, and the part of the cathode electrode CE overlapping the third anode electrodes AE3′ may constitute the third light-emitting element LD3′.

An encapsulation layer TFE is disposed on the cathode electrode CE. The encapsulation layer TFE may prevent oxygen, moisture, or the like from penetrating into the light-emitting element layer LDL′.

An adhesive layer APL, an optical functional layer OFL, an overcoat layer OC, and a cover window CW are disposed on the encapsulation layer TFE. The adhesive layer APL, the optical functional layer OFL, the overcoat layer OC, and the cover window CW are configured similarly to the adhesive layers APL, optical functional layers OFL, overcoat layers OC, and cover windows CW of FIG. 21, respectively. Duplicate explanations of these are omitted.

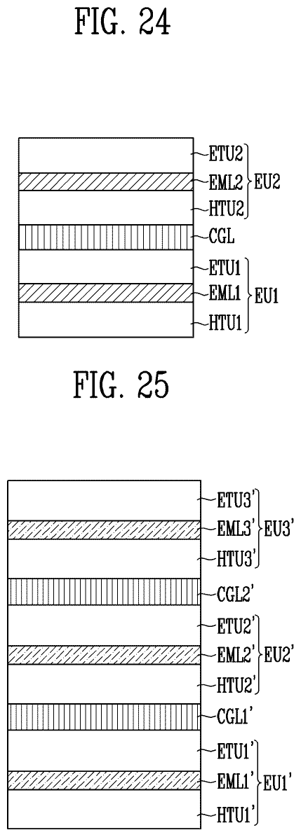

FIG. 24 is a cross-sectional view showing an embodiment of a part of a light-emitting structure included in any one of the first to third light-emitting elements LD1 to LD3 in FIG. 21 and the first to third light-emitting elements LD1′ to LD3′ in FIG. 22.

Referring to FIG. 24, the light-emitting structure may have a tandem structure in which the first and second light-emitting units EU1 and EU2 are stacked. The light-emitting structure may be configured substantially identically in each of the first to third light-emitting elements LD1 to LD3 of FIG. 21.

Each of the first and second light-emitting units EU1, EU2 may comprise at least one light-emitting layer which generates light according to the applied current. The first light-emitting units EU1 may include a first light-emitting layer EML1, a first electron transporting unit ETU1, and a first hole transporting unit HTU1. The first light-emitting layer EML1 may be disposed between the first electron transporting unit ETU1 and the first hole transporting unit HTU1. The second light-emitting unit EU2 may include a second light-emitting layer EML2, a second electron transporting unit ETU2, and a second hole transporting unit HTU2. The second light-emitting layer EML2 may be disposed between the second electron transporting unit ETU2 and the second hole transporting unit HTU2.

Each of the first and second hole transporting units HTU1 and HTU2 may include at least one of a hole injection layer and a hole transporting layer, and may further include a hole buffer layer, an electron blocking layer, or the like as desired. The first and second hole transporting units HTU1 and HTU2 may have the same configuration or different configurations.

Each of the first and second electron transporting units ETU1 and ETU2 may include at least one of an electron injection layer and an electron transporting layer, and may further include an electron buffer layer, a hole blocking layer, or the like as desired. The first and second electron transporting units ETU1 and ETU2 may have the same configuration or different configurations from each other.

A connecting layer, which may be provided in the form of a charge-generation layer CGL, may be disposed between the first and second light-emitting units EU1 and EU2 to connect them to one another. In an embodiment, the charge-generation layer CGL may have a stacked structure of a p-dopant layer and an n-dopant layer. In an embodiment, the p-dopant layer may include p-type dopants such as HAT-CN, TCNQ, NDP-9, etc., and the n-dopant layer may include alkali metals, alkaline earth metals, lanthanide-based metals, or combinations thereof, for example. However, the disclosure is not limited thereto.

In an embodiment, the first light-emitting layer EML1 and the second light-emitting layer EML2 may generate light of different colors from each other. The light emitted from each of the first light-emitting layer EML1 and the second light-emitting layer EML2 may be mixed and visually recognized as white light. In an embodiment, the first light-emitting layer EML1 may generate blue-colored light, and the second light-emitting layer EML2 may generate yellow-colored light, for example. In an embodiment, the second light-emitting layer EML2 may include a structure in which a first sub-light-emitting layer which generates red-colored light and a second sub-light-emitting layer which generates green-colored light are stacked. The red-colored light and the green-colored light may be mixed to provide yellow-colored light. In this case, an intermediate layer which performs a function of transporting holes and/or a function of blocking the transport of electrons may be further disposed between the first and second sub-emitting layers.

In other embodiments, the first light-emitting layer EML1 and the second light-emitting layer EML2 may generate light of the same color.

The light-emitting structure may be formed by vacuum deposition, inkjet printing, or the like, but the disclosure is not limited thereto.

FIG. 25 is a cross-sectional view showing another embodiment of a portion of a light-emitting structure included in any one of the first to third light-emitting elements LD1 to LD3 of FIG. 21 and the first to third light-emitting elements LD1′ to LD3′ of FIG. 22.

Referring to FIG. 25, the light-emitting structure may have a tandem structure in which the first to third light-emitting units EU1′ to EU3′ are stacked. The light-emitting structure may be configured substantially identically in each of the first to third light-emitting elements LD1 to LD3 of FIG. 21.

Each of the first to third light-emitting units EU1′ to EU3′ may comprise a light-emitting layer which generates light according to the applied current. The first light-emitting unit EU1′ may include a first light-emitting layer EML1′, a first electron transporting unit ETU1′, and a first hole transporting unit HTU1′. The first light-emitting layer EML1′ may be disposed between the first electron transporting unit ETU1′ and the first hole transporting unit HTU1′. The second light-emitting unit EU2′ may include a second light-emitting layer EML2′, a second electron transporting unit ETU2′, and a second hole transporting unit HTU2′. The second light-emitting layer EML2′ may be disposed between the second electron transporting unit ETU2′ and the second hole transporting unit HTU2′. The third light-emitting unit EU3′ may include a third light-emitting layer EML3′, a third electron transporting unit ETU3′, and a third hole transporting unit HTU3′. The third emitting layer EML3′ may be disposed between the third electron transporting unit ETU3′ and the third hole transporting unit HTU3′.

Each of the first to third hole transporting units HTU1′ to HTU3′ may include at least one of a hole injection layer and a hole transporting layer, and may further include a hole buffer layer, an electron blocking layer, or the like as desired. The first to third hole transporting units HTU1′ to HTU3′ may have the same configuration or different configurations.

Each of the first to third electron transporting units ETU1′ to ETU3′ may include at least one of an electron injection layer and an electron transporting layer, and may further include an electron buffer layer, a hole blocking layer, or the like as desired. The first to third electron transporting units ETU1′ to ETU3′ may have the same configuration or different configurations from each other.

A first charge-generation layer CGL1′ is disposed between the first and second light-emitting units EU1′ and EU2′. A second charge-generation layer CGL2′ is disposed between the second light-emitting unit EU2′ and the third light-emitting unit EU3′.

In an embodiment, the first to third light-emitting layers EML1′ to EML3′ may produce light of different colors from each other. The light emitted from each of the first to third light-emitting layers EML1′ to EML3′ may be mixed and viewed as white light. In an embodiment, the first emitting layer EML1′ may produce blue-colored light, the second light-emitting layer EML2′ may produce green-colored light, and the third emitting layer EML3′ may produce red-colored light, for example.

In other embodiments, two or more of the first through third light-emitting layers EML1′ through EML3′ may produce light of the same color.

Unlike shown in FIGS. 24 and 25, the light-emitting structure EMS of FIG. 21 may include one light-emitting unit in each of the first to third light-emitting elements LD1 to LD3. In an alternative embodiment, unlike shown in FIGS. 24 and 25, the light-emitting structure EMS' of FIG. 22 may include one light-emitting unit in each of the first to third light-emitting elements LD1′ to LD3′. In this case, the light-emitting units included in each of the first to third light-emitting elements LD1 to LD3 in FIG. 24 or the first to third light-emitting elements LD1′ to LD3′ in FIG. 25 may emit light of different colors. In an embodiment, as shown in FIG. 24, the light-emitting unit of the first light-emitting element LD1 may emit red-colored light, the light-emitting unit of the second light-emitting element LD2 may emit green-colored light and the light-emitting unit of the third light-emitting element LD3 may emit blue-colored light, for example. In this case, the light-emitting units of the first to third sub-pixels SP1 to SP3 are separated from each other, and each of them may be disposed in an opening (refer to OP of FIG. 21 and OP′ of FIG. 22) of the pixel defining layer (refer to PDL of FIG. 21, and PDL′ of FIG. 22). In this case, at least some of the color filters CF1 to CF3 may be omitted.

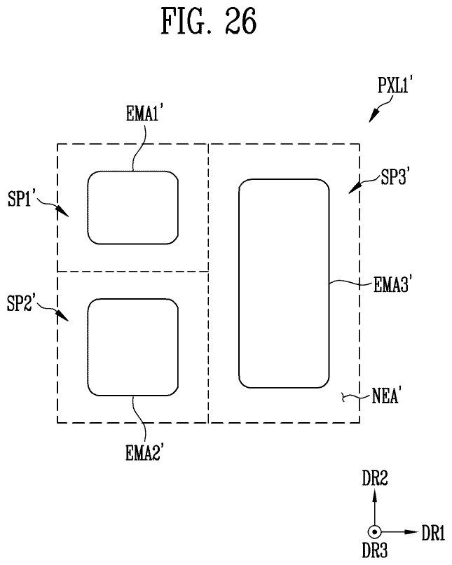

FIG. 26 is a plan view showing another embodiment of any one of the pixels of FIG. 19.

Referring to FIG. 26, the first pixel PXL1′ may include first to third sub-pixels SP1′ to SP3′.

The first sub-pixel SP1′ may comprise a first light-emitting area EMA1′ and a non-light-emitting area NEA′ around the first light-emitting area EMA1′. The second sub-pixel SP2′ may comprise a second light-emitting area EMA2′ and a non-light-emitting area NEA′ around the second light-emitting area EMA2′. The third sub-pixel SP3′ may include a third light-emitting area EMA3′ and a non-light-emitting area NEA′ around the third light-emitting area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have a larger area than the first sub-pixel SP1′, and the third sub-pixel SP3′ may have a greater area than the second sub-pixel SP2′. Accordingly, the second light-emitting area EMA2′ may have a larger area than the first light-emitting area EMA1′, and the third light-emitting area EMA3′ may have a greater area than the second light-emitting area EMA2′. However, embodiments are not so limited. In an embodiment, the first and second sub-pixels SP1′ and SP2′ may have substantially the same area as each other, and the third sub-pixel SP3′ may have a larger area than each of the first and second sub-pixels SP1′ and SP2′, for example. As such, the areas of the first to third sub-pixels SP1′ to SP3′ may be variously modified.

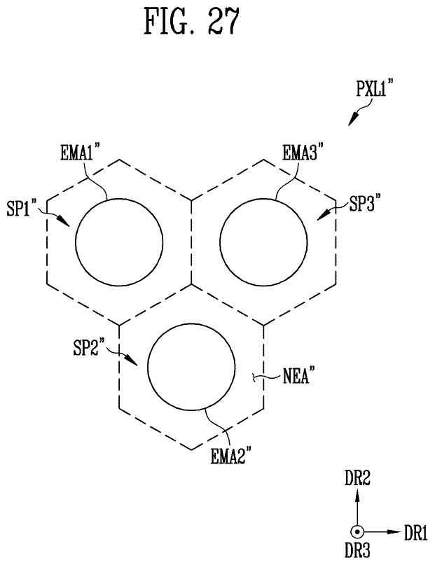

FIG. 27 is a plan view showing another embodiment of any one of the pixels of FIG. 19.

Referring to FIG. 27, the first sub-pixel SP1″ of the first pixel PXL1″ may include a first light-emitting area EMA1″ and a non-light-emitting area NEA″ around the first light-emitting area EMA1″. The second sub-pixel SP2″ of the first pixel PXL1″ may comprise a second light-emitting area EMA2″ and a non-light-emitting area NEA″ around the second light-emitting area EMA2″. The third sub-pixel SP3″ of the first pixel PXL1″ may comprise a third light-emitting area EMA3″ and a non-light-emitting area NEA″ around the third light-emitting area EMA3″.

The first to third sub-pixels SP1″ to SP3″ may have polygonal shapes when viewed in the third direction DR3. In an embodiment, the shapes of the first to third sub-pixels SP1″ to SP3″ may be hexagons as shown in FIG. 27, for example.

The first to third light-emitting areas EMA1″ to EMA3″ may have circular shapes when viewed in the third direction DR3. However, embodiments are not so limited. In an embodiment, each of the first to third light-emitting areas EMA1″ to EMA3″ may have a polygonal shape, for example.

The first and third sub-pixels SP1″, SP3″ may be arranged in the first direction DR1. The second sub-pixel SP2″ may be disposed with respect to the first sub-pixel SP1″ in a direction (or diagonal direction) inclined by an acute angle with respect to the second direction DR2.

The arrangement of sub-pixels shown in FIGS. 20, 26, and 27 is illustrative, and the disclosure is not limited thereto. Each pixel may include two or more sub-pixels, and the sub-pixels may be arranged in various ways. Each of the sub-pixels may have various shapes, and each of its light-emitting regions may have various shape.

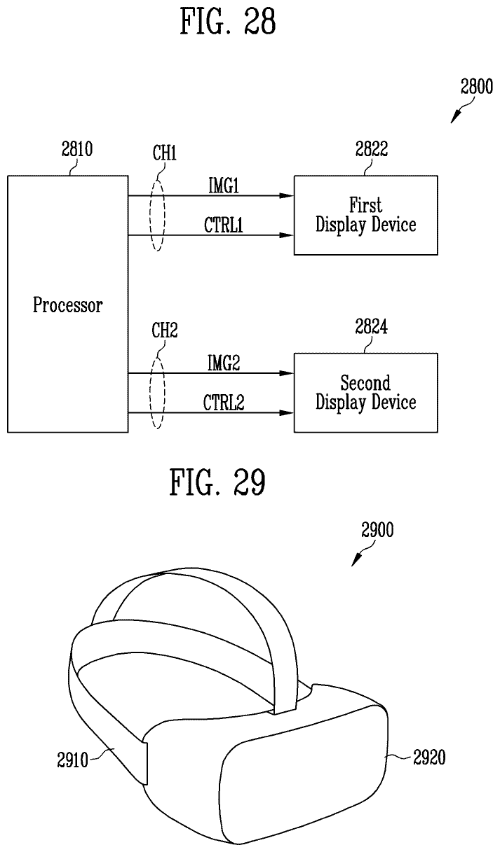

FIG. 28 is a block diagram illustrating an embodiment of a display system 2800.

Referring to FIG. 28, a display system 2800 may include a processor 2810 and one or more display devices 2822 and 2824.

The display system 2800 in embodiments of the disclosure may be also referred to as an electronic device 2800.

The processor 2810 may perform various tasks and calculations. In an embodiment, processor 2810 may include an Application Processor (“AP”), a Graphic Processing Unit (“GPU”), a microprocessor, a Central Processing Unit (“CPU”), etc. The processor 2810 may be connected to other components of the display system 2800 through a bus system to control them.

In FIG. 28, a display system 2800 is shown to include first and second display devices 2822, 2824. The processor 2810 may be connected to the first display device 2822 through the first channel CH1, and connected to the second display device 2824 through the second channel CH2.

Through the first channel CH1, the processor 2810 may transmit the first image data IMG1 and the first control signal CTRL1 to the first display device 2822. The first display device 2822 may display an image based on the first image data IMG1 and the first control signal CTRL1. The first display device 2822 may be configured similarly to the display device 100 described with reference to FIG. 1. In this case, the first image data IMG1 and the first control signal CTRL1 may be respectively provided as the input image data IMG and the control signal CTRL of FIG. 1.

Through the second channel CH2, the processor 2810 may transmit the second image data IMG2 and the second control signal CTRL2 to the second display device 2824. The second display device 2824 may display an image based on the second image data IMG2 and the second control signal CTRL2. The second display device 2824 may be configured similarly to the display device 100 described with reference to FIG. 1. In this case, the second image data IMG2 and the second control signal CTRL2 may be respectively provided as the input image data IMG and the control signal CTRL of FIG. 1.

The display system 2800 may include a portable computer, a mobile phone, a smart phone, a tablet personal computer (“PC”), and a computing system that provides image display functions such as a smart watch, a watch phone, a portable multimedia player (“PMP”), navigation, an ultra-mobile personal computer (“UMPC”), or the like. In addition, the display system 2800 may include at least one of a HMD device, a VR device, an MR device, and an AR device.

FIG. 29 is a perspective view showing an embodiment of an application of the display system 2800 of FIG. 28.

Referring to FIG. 29, the display system 2800 of FIG. 28 may be applied to the HMD device 2900. The HMD device 2900 may be a wearable electronic device that may be worn on a user's head.

The HMD device 2900 may include a head-mounted band 2910 and a display device storage case 2920. The head-mounted band 2910 may be connected to the display device storage case 2920. The head-mounted band 2910 may include a horizontal band and/or a vertical band for securing the HMD device 2900 to the user's head. The horizontal band may surround a side of the user's head, and the vertical band may be configured so as to surround an upper portion of a user's head. However, the disclosure is not limited thereto. In an embodiment, the head-mounted band 2910 may be implemented in the form of an eyeglass frame, a helmet, or the like, for example.

The display device storage case 2920 may store the first and second display devices 2822 and 2824 of FIG. 28. The display device storage case 2920 may further store the processor 2810 of FIG. 28.

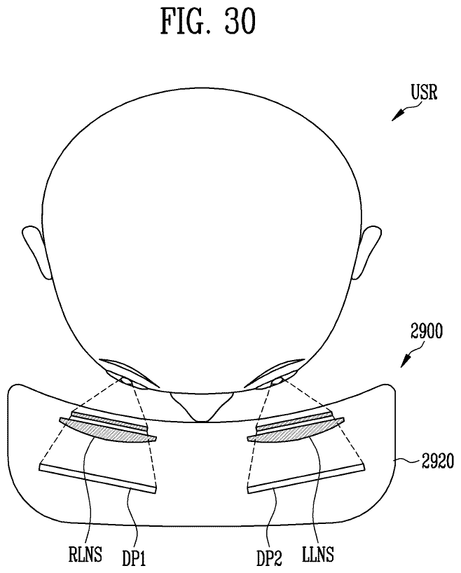

FIG. 30 is a diagram showing an HMD device 2900 worn by the user USR of FIG. 29.

Referring to FIG. 30, a first display panel DP1 of a first display device 2822 and a second display panel DP2 of a second display device 2824 are disposed in the HMD device 2900. The HMD device 2900 may further include one or more lenses LLNS, and/or one or more RLNS.

In the display device storage case 2920, the right eye lens RLNS may be disposed between the first display panel DP1 and the right eye of the user USR. In the display device storage case 2920, the left eye lens LLNS may be disposed between the second display panel DP2 and the left eye of the user USR.

The image output from the first display panel DP1 may be shown to the right eye of the user through the right eye lens RLNS. The right eye lens RLNS may refract light from the first display panel DP1 toward the right eye of the user USR. The right eye lens RLNS may perform an optical function for adjusting a viewing distance between the first display panel DP1 and the right eye of the user USR.

The image output from the second display panel DP2 may be displayed on the left eye of the user through the left eye lens LLNS. The left eye lens LLNS may refract light from the second display panel DP2 toward the left eye of the user USR. The left eye lens LLNS may perform an optical function for adjusting the viewing distance between the second display panel DP2 and the left eye of the user USR.

In an embodiment, each of the right eye lens RLNS and the left eye lens LLNS may include an optical lens having a pancake-shaped cross-section. In an embodiment, each of the right eye lens RLNS and the left eye lens LLNS may include a multi-channel lens including sub-regions having different optical properties. In this case, each display panel outputs images respectively corresponding to the sub-areas of the multi-channel lens, and the output images may be respectively shown to the user through the corresponding sub-areas.

According to the sub-pixel, the display device including the sub-pixel, the electronic device including the display device, and the driving method thereof in embodiments of the disclosure, visibility may be improved.

The drawings and detailed description of the disclosure so far referred to are merely illustrative of the disclosure, which has been used merely for the purpose of describing the disclosure and not for the purpose of limiting the scope of the disclosure as defined in the claims. It will therefore be appreciated by those skilled in the art that various modifications and equivalent embodiments are possible therefrom. Therefore, the true technical protection scope of the disclosure should be determined by the technical idea of the appended claims.

What is claimed is:

1. A sub-pixel comprising:
a first transistor including a gate electrode electrically connected to a first node, the first transistor being connected between a second node and a third node, the second node being electrically connected to a first power line;
a light-emitting element connected between the second node and a second power line;
a second transistor configured to switch an electrical connection between the first node and a data line;
a third transistor configured to switch an electrical connection between the second node and a third power line;
a fourth transistor configured to switch an electrical connection between the first power line and the third node;
a first capacitor configured to maintain a potential difference between the first node and the third node;
a second capacitor configured to maintain a potential difference between the second node and a power line to which a constant voltage is applied; and
a third capacitor configured to maintain a potential difference between the first node and the third node.

2. The sub-pixel according to claim 1, wherein the second capacitor includes a first electrode electrically connected to the second node and a second electrode electrically connected to the power line to which the constant voltage is applied.

3. The sub-pixel according to claim 2, wherein a second power supply voltage is applied to the second power line, and
wherein the constant voltage is identical to the second power supply voltage.

4. The sub-pixel according to claim 2, wherein a third power supply voltage is applied to the third power line, and
the constant voltage is identical to the third power supply voltage.

5. The sub-pixel according to claim 2, wherein the power line to which the constant voltage is applied is different from the first power line, the second power line, and the third power line.

6. The sub-pixel according to claim 2, wherein the first electrode of the second capacitor and the second electrode of the second capacitor are disposed in a same layer.

7. The sub-pixel according to claim 6, wherein a capacitance of the second capacitor is greater than a capacitance between an anode electrode and a cathode electrode of the light-emitting element.

8. The sub-pixel according to claim 1, wherein the first transistor, the second transistor, and the fourth transistor include a P-type semiconductor, and
wherein the third transistor includes an N-type semiconductor.

9. The sub-pixel according to claim 8, wherein a first power supply voltage is applied to the first power line, and a third power supply voltage is applied to the third power line,
wherein the first power supply voltage is applied to body electrodes of the first transistor, the second transistor, and the fourth transistor, respectively, and
wherein the third power supply voltage is applied to a body electrode of the third transistor.

10. A display device comprising:
a display panel including:
a plurality of data lines;
a plurality of first gate lines;
a plurality of light emission control lines;
a plurality of sub-pixels electrically connected to the plurality of data lines, the plurality of first gate lines, the plurality of second gate lines and plurality of light emission control lines, at least one of the plurality of sub-pixels comprising:
a first transistor including a gate electrode electrically connected to a first node, the first transistor being connected between a second node and a third node, the second node being electrically connected to a first power line;
a light-emitting element connected between the second node and a second power line;
a second transistor configured to switch an electrical connection between the first node and a corresponding one of the plurality of data lines;
a third transistor configured to switch an electrical connection between the second node and a third power line;
a fourth transistor configured to switch an electrical connection between the first power line and the third node;
a first capacitor configured to maintain a potential difference between the first node and the third node;
a second capacitor configured to maintain a potential difference between the second node and a power line to which a constant voltage is applied; and
a third capacitor configured to maintain a potential difference between the first node and the third node;
a data driver configured to supply a data voltage to the plurality of data lines; and
a gate driving circuit configured to supply a signal to the plurality of first gate lines, the plurality of second gate lines, and the plurality of light emission control lines.

11. The display device according to claim 10, wherein the second transistor includes a gate electrode electrically connected to a corresponding one of the plurality of first gate lines.

12. The display device according to claim 11, wherein the second transistor is turned on in response to a first scan signal having a low-level applied to the gate electrode.

13. The display device according to claim 10, wherein the third transistor includes a gate electrode electrically connected to a corresponding one of the plurality of second gate lines.

14. The display device according to claim 13, wherein the third transistor is turned on in response to a second scan signal having a high-level applied to the gate electrode.

15. An electronic device comprising:
a processor which outputs an input image data;
a controller which converts the input image data to output an image data;
a display panel including:
a plurality of data lines;
a plurality of first gate lines;
a plurality of second gate lines;
a plurality of sub-pixels electrically connected to the plurality of data lines, the plurality of first gate lines, the plurality of second gate lines, at least one of the plurality of sub-pixels comprising:
a first transistor including a gate electrode electrically connected to a first node, the first transistor being connected between a second node and a third node, the second node being electrically connected to a first power line;
a light-emitting element connected between the second node and a second power line;
a second transistor configured to switch an electrical connection between the first node and a corresponding one of the plurality of data lines;
a third transistor configured to switch an electrical connection between the second node and a third power line;
a fourth transistor configured to switch an electrical connection between the first power line and the third node;
a first capacitor configured to maintain a potential difference between the first node and the third node;
a second capacitor configured to maintain a potential difference between the second node and a power line to which a constant voltage is applied; and
a third capacitor configured to maintain a potential difference between the first node and the third node;
a data driver configured to supply a data voltage corresponding to the image data to the plurality of data lines; and
a gate driving circuit configured to supply a signal to the plurality of first gate lines, the plurality of second gate lines, and the plurality of light emission control lines.

16. The electronic device according to claim 15, wherein the controller generates the image data based on the capacitance of the first capacitor and the capacitance of the third capacitor.

17. The electronic device according to claim 15, wherein the second capacitor includes a first electrode electrically connected to the second node and a second electrode electrically connected to the power line to which the constant voltage is applied.

18. The electronic device according to claim 17, wherein a second power supply voltage is applied to the second power line, and
wherein the constant voltage is identical to the second power supply voltage.

19. The electronic device according to claim 17, wherein a third power supply voltage is applied to the third power line, and
the constant voltage is identical to the third power supply voltage.

20. The electronic device according to claim 15, wherein the first transistor, the second transistor, and the fourth transistor include a P-type semiconductor, and
wherein the third transistor includes an N-type semiconductor.
